(19) United States
(12) Patent Application Publication
(10) Pub. No.: US 2025/0241147 A1
(43) Pub. Date: Jul. 24, 2025

(54) DISPLAY DEVICE

(71) Applicant: Samsung Display Co., Ltd., Yongin-si (KR)

(72) Inventors: SUNGSIK YUN, Yongin-si (KR); JU-YEON SEO, Yongin-si (KR)

(21) Appl. No.: 18/923,484

(22) Filed: Oct. 22, 2024

(30) Foreign Application Priority Data
Jan. 18, 2024 (KR) 10-2024-0008330

(51) Int. Cl. H10K 59/131; H10K 59/124; H10K 59/40; H10K 102/00

(52) U.S. Cl. CPC H10K 59/131; H10K 59/124; H10K 59/40; H10K 2102/311

(57) ABSTRACT

A display device includes: a display panel including: a first area including an active area including pixels; a second area bent around a bending axis extending in a first direction; and a third area spaced from the first area with the second area therebetween in a second direction crossing the first direction; and an input sensor including a first conductive layer on a first sensing insulation layer, and covered by a second sensing insulation layer; and a second conductive layer on the second sensing insulation layer, and covered by a third sensing insulation layer. The third area includes a bonding area extending to opposite ends of the third area in the first direction, and located adjacent to the second area. The first sensing insulation layer, the second sensing insulation layer, conductive patterns of the third area, and the third sensing insulation layer are located in the bonding area.

### CROSS-REFERENCE TO RELATED APPLICATION

The present application claims priority to and the benefit of Korean Patent Application No. 10-2024-0008330, filed on Jan. 18, 2024, in the Korean Intellectual Property Office, the entire disclosure of which is incorporated by reference herein.

### BACKGROUND

### 1. Field

Aspects of embodiments of the present disclosure relate to a display device, and more particularly, to a display device having improved reliability.

### 2. Description of the Related Art

Various display devices may be used in various multimedia devices, such as televisions, mobile phones, tablet computers, navigation units, and game consoles. Recently, display panels, each including one area that is bent to be accommodated in a housing, are developed in order to reduce dead spaces of the display devices.

The above information disclosed in this Background section is for enhancement of understanding of the background of the present disclosure, and therefore, it may contain information that does not constitute prior art.

### SUMMARY

One or more embodiments of the present disclosure may be directed to a display device that blocks a path through which moisture introduced into a bending area of a display panel may intrude.

According to one or more embodiments of the present disclosure, a display device includes: a display panel including: a first area including an active area including pixels; a second area bent around a bending axis extending in a first direction; and a third area spaced from the first area with the second area therebetween in a second direction crossing the first direction, the third area including a driving chip, conductive patterns, and pads; and an input sensor including: first to third sensing insulation layers on the display panel; a first conductive layer on the first sensing insulation layer, and covered by the second sensing insulation layer; and a second conductive layer on the second sensing insulation layer, and covered by the third sensing insulation layer. The third area further includes a bonding area extending to opposite ends of the third area in the first direction, the bonding area being located adjacent to the second area. The first sensing insulation layer, the second sensing insulation layer, the conductive patterns that are in contact with the first sensing insulation layer and the second sensing insulation layer, and the third sensing insulation layer are located in the bonding area.

In an embodiment, each of the first sensing insulation layer and the second sensing insulation layer may include an inorganic material, and the third sensing insulation layer may include an organic material.

In an embodiment, the conductive patterns may include the same material as that of one of the first conductive layer or the second conductive layer.

In an embodiment, the display panel may include: a base layer; a light blocking pattern on the base layer; a barrier layer on the light blocking pattern; a buffer layer on the barrier layer; first to seventh insulation layers on the buffer layer; transistors of each of the pixels; a pixel defining layer on the seventh insulation layer; light emitting elements connected to the transistors; and an encapsulation layer covering the light emitting elements. Each of the barrier layer, the buffer layer, and the first to fifth insulation layers may include an inorganic material, and each of the sixth and seventh insulation layers may include an organic material.

In an embodiment, in a cross-section view in the second direction, the base layer, the barrier layer, the buffer layer, and the first to fifth insulation layers may be located in the bonding area, and an opening portion overlapping with the bonding area and exposing the fifth insulation layer may be defined in the sixth insulation layer and the seventh insulation layer.

In an embodiment, the first sensing insulation layer, the conductive patterns, the second sensing insulation layer, and the third sensing insulation layer located in the bonding area may overlap with the opening portion.

In an embodiment, the display panel may include: data lines connected to the pixels and the driving chip; and power lines connected to the pixels and the pads. The data lines and the power lines may be located in the first area and the third area, and may be disconnected in the second area. The third area may include a data line area including the data lines, and a power line area including the power lines.

In an embodiment, the data lines may be located on the second insulation layer, and may be covered by the third insulation layer. The power lines may be located on the sixth insulation layer, and may be covered by the seventh insulation layer. The display device may further include: a first bridge pattern in the second area, and connected to the data lines located in the first area and the data lines located in the third area; and a second bridge pattern in the second area, and connected to the power lines located in the first area and the power lines located in the third area.

In an embodiment, an opening portion that passes through the barrier layer, the buffer layer, and the first to fifth insulation layers to expose the base layer may be defined in the second area. A portion of each of the sixth insulation layer, the seventh insulation layer, and the pixel defining layer may cover the opening portion. The first bridge pattern and the second bridge pattern may be located on the sixth insulation layer, and may be covered by the seventh insulation layer.

In an embodiment, in a cross-sectional view of the bonding area and the data line in the second direction, the first bridge pattern may be connected to the data lines through a contact hole passing through the third to sixth insulation layers.

In an embodiment, in a cross-sectional view of the bonding area and the power line area in the second direction, one end of a conductive pattern from among the conductive patterns may be connected to the second bridge pattern through a first contact hole defined in the seventh insulation layer and the first sensing insulation layer, and another end of the conductive pattern may be connected to the power line through a second contact hole defined in the seventh insulation layer and the first sensing insulation layer.

In an embodiment, the display device may further include an upper conductive pattern on the second sensing insulation layer within the bonding area, the upper conductive pattern being covered by the third sensing insulation layer and overlapping with the conductive patterns.

In an embodiment, in a cross-sectional view of the bonding area and the power line area in the second direction, the upper conductive pattern may be connected to a conductive pattern from among the conductive patterns through contact holes defined in the second sensing insulation layer.

In an embodiment, the display device may further include a lower connection pattern on the fourth insulation layer, and covered by the fifth insulation layer. One end of the lower connection pattern may be connected to the second bridge pattern, and another end of the lower connection pattern may be connected to the power line via the bonding area.

In an embodiment, the display device may further include a lower connection pattern on the fourth insulation layer, and covered by the fifth insulation layer. In a cross-sectional view of the bonding area and the power line area in the second direction, a conductive pattern from among the conductive patterns may be spaced from the second bridge pattern and the power line. One end of the lower connection pattern may be connected to the second bridge pattern, and another end of the lower connection pattern may be connected to the power line via the bonding area.

In an embodiment, in a cross-sectional view of the bonding area and the data line area in the second direction, the first sensing insulation layer, the conductive patterns, and the second sensing insulation layer may expose a side surface of each of the sixth and seventh insulation layers, which may be adjacent to the second area and may define the opening portion, and a top surface of the fifth insulation layer. The third sensing insulation layer may cover the exposed side surfaces of the sixth and seventh insulation layers.

In an embodiment, the encapsulation layer may include: a first inorganic encapsulation layer covering the light emitting elements; a second inorganic encapsulation layer on the first inorganic encapsulation layer; and an organic encapsulation layer between the first inorganic encapsulation layer and the second inorganic encapsulation layer. The display device may further include a dam pattern in the first area adjacent to the second area, the dam pattern including a plurality of layers, and a boundary of the organic encapsulation layer may be defined in the first area by the dam pattern.

In an embodiment, the first inorganic encapsulation layer and the second inorganic encapsulation layer may be in contact with each other between the dam pattern and the second area, and the first inorganic encapsulation layer and the second inorganic encapsulation layer may not be located in the second area and the third area.

In an embodiment, the first area may include an additional bonding area extending to opposite ends of the first area in the first direction, the additional bonding area being adjacent to the second area, and the first sensing insulation layer and the second sensing insulation layer may be in contact with each other in the additional bonding area.

In an embodiment, the input sensor may include trace lines connected to the second conductive layer and the pads, the third area may include a trace line area including the trace lines, and the trace line area may overlap with the power line area.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is an exploded perspective view of a display device according to an embodiment of the present disclosure;

FIG. 3 is a cross-sectional view taken along the line I-I′ in FIG. 2;

FIG. 4 is a cross-sectional view illustrating a display device in a state in which a display panel is bent according to an embodiment of the present disclosure;

FIG. 5A is a plan view of a display panel according to an embodiment of the present disclosure;

FIG. 5B is an enlarged plan view of one area of a display panel according to an embodiment of the present disclosure;

FIG. 6 is a plan view of an input sensor according to an embodiment of the present disclosure;

FIG. 7 is a cross-sectional view of a display module according to an embodiment of the present disclosure;

FIG. 8 is a cross-sectional view taken along the line III-III′ in FIG. 5B;

FIG. 9 is a cross-sectional view taken along the line IV-IV′ in FIG. 5B;

FIG. 10 is a cross-sectional view of a bonding area of a display panel according to an embodiment of the present disclosure;

FIG. 11 is a cross-sectional view of a bonding area of a display panel according to an embodiment of the present disclosure;

FIG. 12 is a cross-sectional view of a bonding area of a display panel according to an embodiment of the present disclosure;

FIG. 13 is a cross-sectional view taken along the line V-V′ in FIG. 5B;

FIG. 14 is a cross-sectional view of a bonding area of a display panel according to an embodiment of the present disclosure;

FIG. 15 is a cross-sectional view of a bonding area of a display panel according to an embodiment of the present disclosure; and

FIG. 16 is a cross-sectional view of a bonding area of a display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

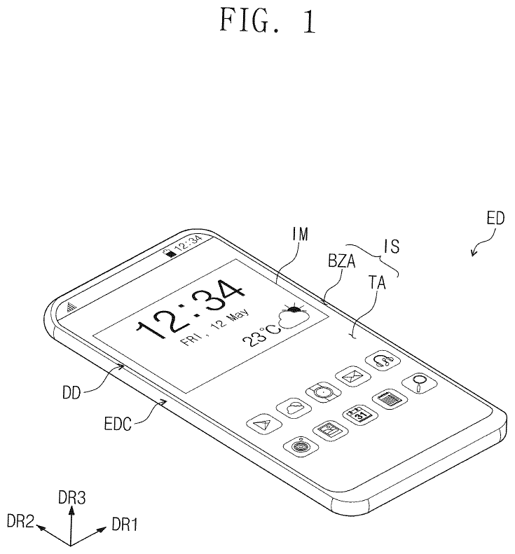

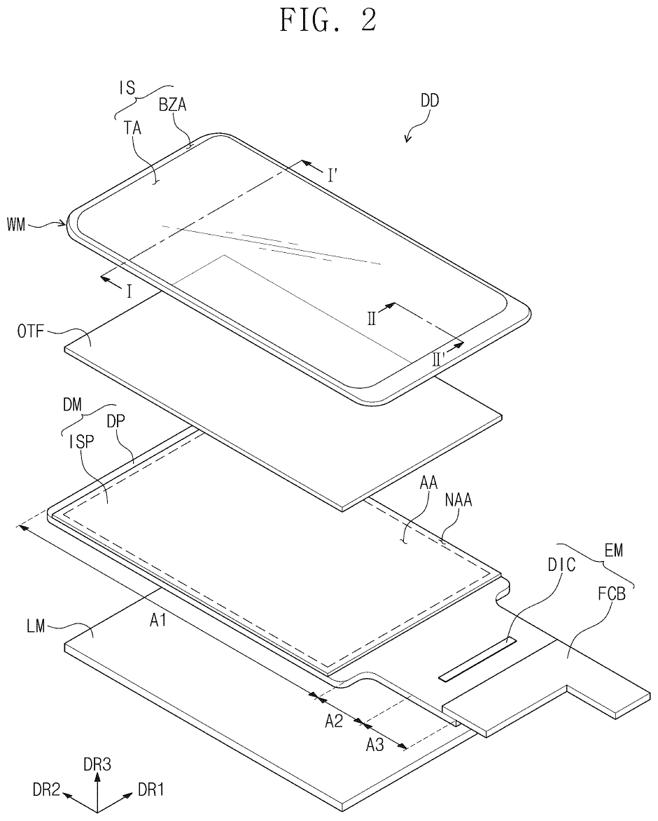

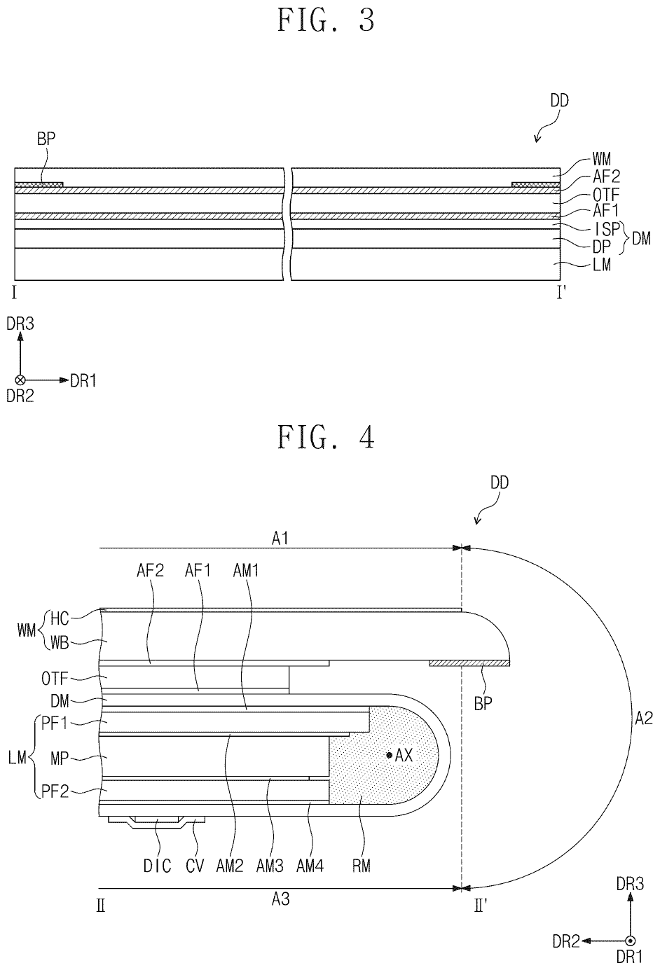

FIG. 1 is a perspective view of a display device according to an embodiment of the present disclosure. FIG. 2 is an exploded perspective view of a display device according to an embodiment of the present disclosure. FIG. 3 is a cross-sectional view taken along the line I-I′ in FIG. 2.

Referring to FIGS. 1 to 3, an electronic device ED may be a device that is activated in response to an electrical signal. The electronic device ED may include various suitable devices. For example, the electronic device ED may include (e.g., may be) a display device DD, such as a smart watch, a tablet computer, a notebook computer, a computer, or a smart television.

The electronic device ED may display an image IM in a third direction DR3 on a display surface IS parallel to or substantially parallel to each of a first direction DR1 and a second direction DR2. The display surface IS on which the image IM is displayed may correspond to a front surface of the electronic device ED. The image IM may include a dynamic image as well as a still image.

In the present embodiment, a front surface (e.g., a top surface) and a rear surface (e.g., a bottom surface) of each member are defined based on the third direction DR3 in which the image IM is displayed. The front surface and the rear surface may oppose each other in the third direction DR3, and a normal direction to each of the front surface and the rear surface may be parallel to or substantially parallel to the third direction DR3.

A spaced distance between the front surface and the rear surface in the third direction DR3 may correspond to a thickness of the electronic device ED in the third direction DR3. However, the directions indicated by the first to third directions DR1, DR2 and DR3 are relative, and may be variously modified to other suitable directions.

The electronic device ED may detect an external input applied from the outside. The external input may include various suitable kinds of inputs provided from the outside of the electronic device ED. For example, the external input may include a touch by a part of a body, such as a user's hand, as well as an external input (e.g., hovering) applied by approaching the electronic device ED or being adjacent thereto by a suitable distance (e.g., a predetermined distance). In addition, the external input may include various suitable kinds of inputs, such as force, pressure, temperature, and/or light.

The display surface IS of the electronic device ED may be divided into a transmission area TA and a bezel area BZA. The transmission area TA may be an area on which the image IM is displayed. A user may view the image IM through the transmission area TA. In the present embodiment, the transmission area TA has a rectangular shape with vertices that are rounded. However, the present disclosure is not limited thereto. The transmission area TA may have various suitable shapes, and is not limited to any particular embodiment.

The bezel area BZA is adjacent to the transmission area TA. The bezel area BZA may have a suitable color (e.g., a predetermined color). The bezel area BZA may surround (e.g., around a periphery of) the transmission area TA. Accordingly, a shape of the transmission area TA may be defined by or substantially by the bezel area BZA. However, the present disclosure is not limited thereto. For example, the bezel area BZA may be disposed to be adjacent to only one side of the transmission area TA, or may be omitted as needed or desired. The electronic device ED of the present disclosure is not limited to any particular embodiment.

The electronic device ED may include the display device DD and an outer case EDC (e.g., a housing). The display device DD may include a window WM, a display module (e.g., a display layer or panel) DM, a driving module (e.g., a driver) EM, an optical film OTF, and a lower module (e.g., a lower layer or panel) LM. The display module DM may include a display panel DP, and an input sensor ISP disposed on the display panel DP. The display panel DP generates the image IM, and the input sensor ISP obtains coordinate information of an external input (e.g., a touch event).

The window WM may be made of a transparent material through which an image is emitted. For example, the window WM may include glass, sapphire, plastic, or the like. The window WM is illustrated as a single layer, but the present disclosure is not limited thereto. For example, the window WM may include a plurality of layers. The bezel area BZA of the display device DD may be provided as or substantially provided as an area in which a material having a suitable color (e.g., a predetermined color) is printed on one area of the window WM.

The display module DM may include the display panel DP, and the input sensor ISP. The display panel DP according to an embodiment of the present disclosure may be an emissive display panel, but the present disclosure is not particularly limited thereto. For example, the display panel DP may be an organic light emitting display panel, an inorganic light emitting display panel, or a quantum-dot light emitting display panel. A light emitting layer of the organic light emitting display panel may include an organic light emitting material, and a light emitting layer of the inorganic light emitting display panel may include an inorganic light emitting material. A light emitting layer of the quantum-dot light emitting display panel may include a quantum dot, a quantum rod, and/or the like. Hereinafter, for convenience, the display panel DP may be described in more detail in the context of the organic light emitting display panel.

The input sensor ISP may be disposed directly on the display panel DP. According to an embodiment of the present disclosure, the input sensor ISP may be formed on the display panel DP through a continuous process. In other words, when the input sensor ISP is disposed directly on the display panel DP, an adhesive film through which the input sensor ISP and the display panel DP may be connected to (e.g., coupled to or attached to) each other is not disposed between the input sensor ISP and the display panel DP.

The optical film OTF reduces a reflectance of external light incident from above the window WM. The optical film OTF according to an embodiment of the present disclosure may include a retarder and a polarizer. The retarder may be a film kind or a liquid crystal coating kind, and may include an ë/2 retarder and/or an ë/4 retarder. The polarizer may also be a film kind or a liquid crystal coating kind. The film kind may include a stretchable synthetic resin film, and the liquid crystal coating kind may include liquid crystals arranged in a desired arrangement (e.g., a predetermined arrangement). The retarder and the polarizer may be provided as a single polarizing film. The optical film OTF may further include a protective film disposed above or below the polarizing film.

The optical film OTF may be disposed on the input sensor ISP. In other words, the optical film OTF may be disposed between the input sensor ISP and the window WM. The input sensor ISP, the optical film OTF, and the window WM may be connected to (e.g., coupled to or attached to) each other through an adhesive layer.

Referring to FIG. 3, a window adhesive layer AF1 may be disposed between the input sensor ISP and the optical film OTF, and an optical adhesive layer AF2 may be disposed between the optical film OTF and the window WM. In other words, the optical film OTF may be connected to (e.g., coupled to or attached to) the input sensor ISP through the window adhesive layer AF1, and the window WM may be connected to (e.g., coupled to or attached to) the optical film OTF through the optical adhesive layer AF2.

In an embodiment of the present disclosure, each of the adhesive layers AF1 and AF2 may include an optically clear adhesive film (OCA). However, the material of each of the adhesive layers AF1 and AF2 is not limited thereto, and the adhesive layers AF1 and AF2 may include a common adhesive or an adhesive agent. For example, each of the adhesive layers AF1 and AF2 may include a pressure sensitive adhesive (PSA), an optical clear adhesive (OCA), or an optical clear resin (OCR).

In addition to the optical film OTF, a functional layer that performs another function, for example, such as a protective layer or the like, may be further disposed between the display module DM and the window WM.

The display module DM may display an image in response to an electrical signal, and transmit/receive information of an external input. The display module DM may be defined as (e.g., may include) an active area AA and a peripheral area NAA. The active area AA may be defined as an area through which an image provided by the display module DM is emitted.

The peripheral area NAA is adjacent to the active area AA. For example, the peripheral area NAA may surround (e.g., around a periphery of) the active area AA. However, the present disclosure is not limited thereto. For example, the peripheral area NAA may be defined as having various suitable shapes, and is not limited to any particular embodiment. According to an embodiment, the active area AA of the display module DM may correspond to at least a portion of the transmission area TA.

According to an embodiment of the present disclosure, the display module DM may include a first area A1, a second area A2, and a third area A3 that are arranged along the second direction DR2. The first area A1 may include the active area AA and a portion of the peripheral area NAA, and the second area A2 and the third area A3 may include the remaining portions of the peripheral area NAA. The second area A2 may be a bending area that is bent around a bending axis, and each of the first area A1 and the third area A3 may be a non-bending area.

A length of each of the second area A2 and the third area A3 in the first direction DR1 may be less than or equal to a length of the first area A1 in the first direction DR1. An area having a smaller length in a bending-axis direction may be more easily bent.

The driving module EM may control driving of the display module DM. The driving module EM may include a flexible circuit film FCB and a driving chip DIC. The flexible circuit film FCB may be electrically connected to the display panel DP. The flexible circuit film FCB may be connected to (e.g., coupled to or attached to) an end of the third area A3 of the display module DM through a bonding process. The flexible circuit film FCB may be electrically connected to the display module DM through an anisotropic conductive adhesive layer. The driving chip DIC may be mounted in the third area A3 of the display module DM. The driving chip DIC may include one or more driving circuits, for example, such as a data driving circuit for driving pixels of the display panel DP.

According to an embodiment, the flexible circuit film FCB may include a ground line through which static electricity introduced into the flexible circuit film FCB or static electricity introduced into the input sensor ISP may be discharged.

The driving module EM may further include a plurality of driving elements mounted on the flexible circuit film FCB. The plurality of driving elements may include a circuit part that converts a signal input from the outside into a signal used for the driving chip DIC, or converts the input signal into a signal used to drive the display module DM. When the second area A2 and the third area A3 of the display module DM are bent, the flexible circuit film FCB may be disposed below (e.g., underneath) the display module DM.

The lower module LM is disposed on a rear surface of the display module DM. Because the lower module LM is disposed on the rear surface of the display module DM, an impact resistance of the display device DD may be improved. The lower module LM may be fixed to the rear surface of the display module DM through an adhesive layer.

When the second area A2 and the third area A3 of the display module DM are bent, the third area A3 of the display module DM and the flexible circuit film FCB may be disposed on a rear surface of the lower module LM.

The outer case EDC may be connected to (e.g., coupled to or attached to) the window WM to define an outer appearance of the electronic device ED. The outer case EDC accommodates the display device DD. The outer case EDC absorbs an impact applied from the outside, and prevents or substantially prevents foreign matters, moisture, and/or the like from being introduced into the electronic device ED to protect the components accommodated in the outer case EDC. As an example of an embodiment of the present disclosure, the outer case EDC may be provided in a suitable shape in which a plurality of accommodation members are connected to (e.g., coupled to or attached to) each other.

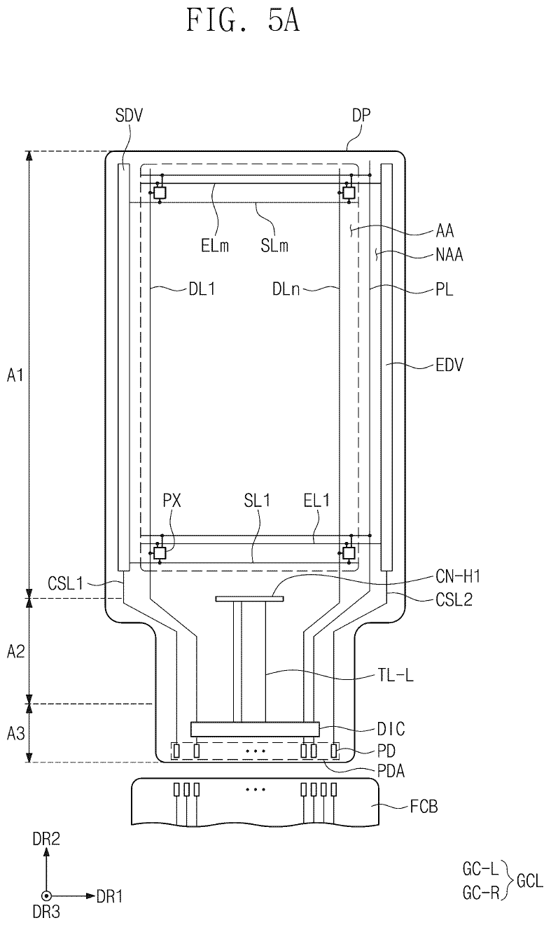

FIG. 4 is a cross-sectional view illustrating a display device in a state in which a display panel is bent according to an embodiment of the present disclosure. FIG. 4 illustrates a cross-sectional view of the display device DD that is adjacent to the second area A2 in a state in which the second area A2 is bent around a bending axis AX extending in the first direction DR1. For example, FIG. 4 may correspond to a cross-section taken along the line II-II′ in FIG. 2 in a state in which one area (e.g., the second area A2) is bent.

The display device DD may include a window WM, an optical film OTF, a display module (e.g., a display layer or panel) DM, and a lower module (e.g., a lower layer or panel) LM. The lower module LM may include a first protective member PF1, a second protective member PF2, and a functional layer MP.

The window WM according to an embodiment may include a base part WB, a hard coating layer HC, and a bezel pattern BP. The base part WB may include an optically transparent insulation material. For example, the base part WB may include a glass substrate or a synthetic resin film. The hard coating layer HC protects the base part WB, and may be disposed on one of a front surface and/or a rear surface of the base part WB. The hard coating layer HC may prevent or substantially prevent the base part WB from being damaged due to scratches or the like. An anti-fingerprint layer may be further disposed on the base part WB.

The bezel pattern BP defines the bezel area BZA (e.g., see FIG. 1) of the window WM. The bezel pattern BP may be disposed to be adjacent to an edge of a rear surface of the base part WB.

The bezel pattern BP may be a colored layer, and may be formed through coating. The bezel pattern BP may include a polymer resin, and a pigment mixed with the polymer resin. For example, the polymer resin may be an acrylic resin or polyester, and the pigment may be a carbon-based pigment.

The optical film OFT may be disposed below the window WM. The optical film OFT may reduce a reflectance of external light incident from the window WM. The window WM and the optical film OTF may be connected to (e.g., coupled to or attached to) each other through a window adhesive layer AF1. The display module DM and the optical film OTF may be connected to (e.g., coupled to or attached to) each other through an optical adhesive layer AF2.

The functional layer MP may be disposed below the first protective member PF1. The functional layer MP and the first protective member PF1 may be connected to (e.g., coupled to or attached to) each other through a second adhesive layer AM2. The functional layer MP may be provided in the form of a plate. The functional layer MP may include a plurality of layers. For example, the functional layer MP may include a light blocking layer, a heat dissipating layer, a cushion layer, and a plurality of adhesive layers.

The light blocking layer may serve to prevent or substantially prevent the components disposed on the display module DM from being viewed through the window WM via active areas AA. The light blocking layer may include a binder, and a plurality of pigment particles dispersed therein. The pigment particles may include carbon black and the like. As the electronic device ED according to an embodiment includes the light blocking layer, the electronic device ED may have improved light blocking properties.

The heat dissipating layer may effectively dissipate heat generated from the display module DM. The heat dissipating layer may include at least one of graphite, copper (Cu), or aluminum (AI), each of which may have suitable heat dissipating characteristics (e.g., good heat dissipating characteristics). However, the present disclosure is not limited thereto. The heat dissipating layer may improve the heat dissipating characteristics, and may also have electromagnetic blocking or absorbing characteristics.

The cushion layer may be in the form of a synthetic resin foam. The cushion layer may include a matrix and a plurality of voids. The cushion layer may have an elasticity and a porous structure.

The matrix may include a flexible material. The matrix may include a synthetic resin. For example, the matrix may include at least one of acrylonitrile butadiene styrene copolymer (ABS), polyurethane (PU), polyethylene (PE), ethylene vinyl acetate (EVA), or polyvinyl chloride (PVC). The plurality of voids may absorb (e.g., may easily absorb) an impact applied to the cushion layer. As the cushion layer has the porous structure, the plurality of voids may be defined.

According to an embodiment, at least one of the light blocking layer, the heat dissipating layer, or the cushion layer that are included in the functional layer MP may be omitted as needed or desired, and/or the plurality of layers may be provided as a single layer. However, the present disclosure is not limited thereto.

The functional layer MP and the second protective member PF2 may be connected to (e.g., coupled to or attached to) each other through a third adhesive layer AM3. The second protective member PF2 may be disposed on a rear surface of the display module DM that overlaps with the third area A3. The display module DM and the second protective member PF2 may be connected to (e.g., coupled to or attached to) each other through a fourth adhesive layer AM4.

The electronic device ED according to an embodiment may further include a protective layer RM. The protective layer RM may be disposed in an inner space defined by the rear surface of the display module DM, which overlaps with the second area A2 when the display module DM is bent, a side surface of the first protective member PF1, a side surface of the functional layer MP, a side surface of the second protective member PF2, and a side surface of each of the adhesive layers AM1, AM2, AM3, and AM4.

As the protective layer RM is disposed in the inner space, when the display module DM is bent, the protective layer RM may support the display module DM to maintain or substantially maintain a shape of the second area A2. In addition, foreign matters or the like may be prevented or substantially prevented from being introduced into the display module DM through the second area A2. The protective layer RM according to an embodiment may include a resin.

The display panel DP according to an embodiment may further include a bending cover layer disposed in the second area A2. The bending cover layer may reduce a stress applied to the second area A2 upon the bending of the second area A2, and may protect the second area A2.

The display panel DD according to an embodiment may further include a conductive film CV disposed in the third area A3. The conductive film CV may cover the driving chip DIC to prevent or substantially prevent static electricity introduced from the outside from damaging the driving chip DIC, and may prevent or substantially prevent foreign matters or the like from being introduced into the driving chip DIC. In addition, an impact may be prevented or substantially prevented from being applied to the driving chip DIC.

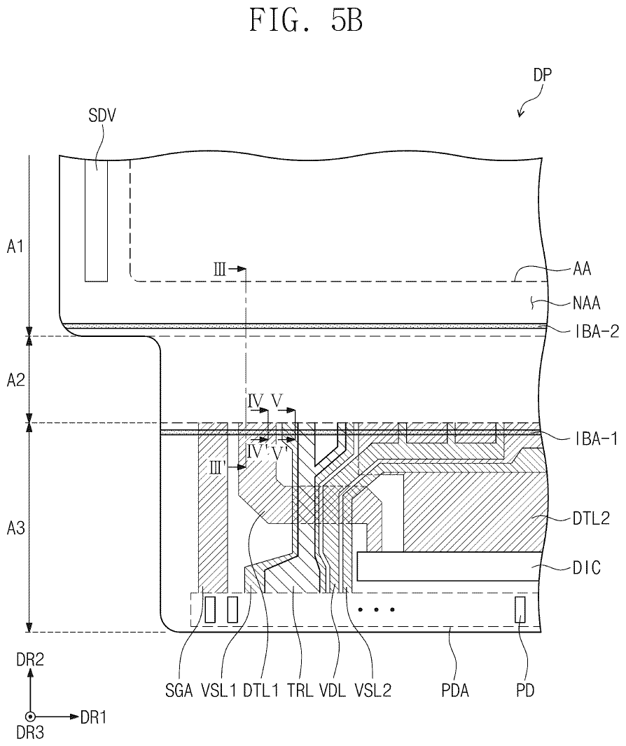

FIG. 5A is a plan view of a display panel according to an embodiment of the present disclosure. FIG. 5B is an enlarged plan view of one area of a display panel according to an embodiment of the present disclosure.

The display panel DP according to an embodiment of the present disclosure may be divided into a first area A1, a second area A2, and a third area A3 that are arranged along the second direction DR2. The first to third areas A1, A2, and A3 of the display panel DP illustrated in FIG. 5A may correspond to the first to third areas A1, A2, and A3 of the display module DM illustrated in FIG. 2, respectively. As used in the present disclosure, “an area/portion corresponding to another area/portion” means that the area/portion overlaps with the other area/portion, and is not limited to the areas/portions having the same surface area as each other.

A display panel DP according to an embodiment may include an active area AA on which a pixel PX is disposed, and a peripheral area NAA adjacent to the active area AA. The active area AA and the peripheral area NAA correspond to the active area AA and the peripheral area NAA illustrated in FIG. 2, respectively. The active area AA corresponds to an area of the first area A1 on which the pixel PX is disposed, and the peripheral area NAA is defined as a remaining area except for the area on which the pixel PX is disposed.

The first area A1 may include the active area AA and a portion of the peripheral area NAA, and the second area A2 and the third area A3 may include remaining portions of the peripheral area NAA.

The display panel DP may include a scan driver SDV, an emission driver EDV, pads PD, and a driving chip DIC on the peripheral area NAA. In the present embodiment, the driving chip DIC may be a data driver.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, and a plurality of pads PD, where m and n are each a natural number. The pixels PX may be connected to the scan lines SL1 to SLm, the data lines DL1 to DLn, and the emission lines EL1 to Elm.

The scan lines SL1 to SLm may extend in the first direction DR1 to be connected to the scan driver SDV. The data lines DL1 to DLn may extend in the second direction DR2 from the first area A1 via the second area A2 to be connected to the driving chip DIC disposed in the third area A3. The emission control lines EL1 to ELm may extend in the first direction DR1 to be connected to the emission driver EDV.

The power line PL may include a portion extending in the first direction DR1 and a portion extending in the second direction DR2. The portion extending in the first direction DR1 and the portion extending in the second direction DR2 may be disposed at (e.g., in or on) different layers from each other. The portion that extends in the second direction DR2 of the power line PL may extend from the first area A1 via the second area A2 to the third area A3. The power line PL may supply a reference voltage to the pixels PX.

The first control line CSL1 may be connected to the scan driver SDV, and may extend from the first area A1 via the second area A2 to the third area A3. The second control line CSL2 may be connected to the emission driver EDV, and may extend from the first area A1 via the second area A2 to the third area A3.

The pads PD may be disposed to be adjacent to an end of the third area A3. The driving chip DIC, the power line PL, the first control line CSL1, and the second control line CSL2 may be connected to the pads PD. The flexible circuit film FCB may be disposed on the display panel DP while overlapping with an end of the third area A3 of the display panel DP. The flexible circuit film FCB may include pads corresponding to the pads PD, and may be electrically connected to the pads PD through an anisotropic conductive film (ACF).

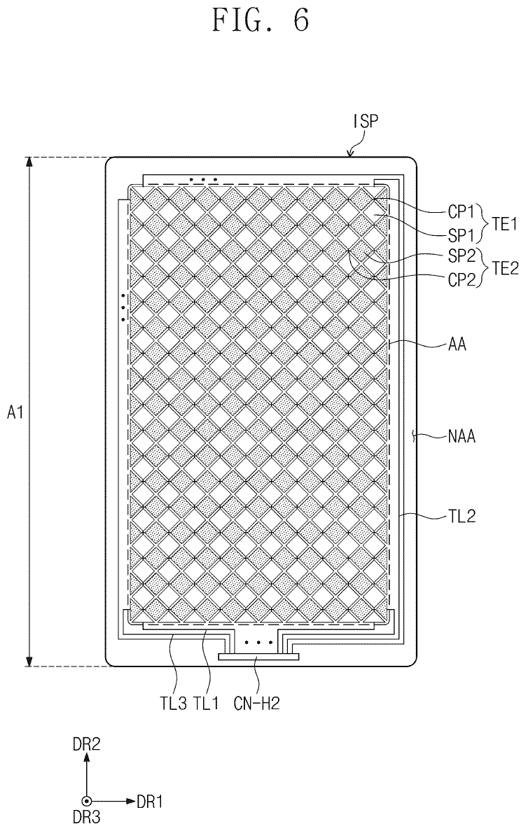

The display panel DP according to an embodiment may include a first contact hole CN-H1 defined in the first area A1. The display panel DP may include extension trace lines TL-L. The extension trace lines TL-L may extend via the first area A1 and the second area A2 to the third area A3. The extension trace lines TL-L may be connected to corresponding lines of trace lines TL1, TL2, and TL3 (e.g., see FIG. 6) to be described in more detail below through the first contact hole CN-H1 in a one-to-one manner. For example, one end of each of the extension trace lines TL-L may be exposed from the first contact hole CN-H1 to be connected to each of (or a corresponding one of) the trace lines TL1, TL2, and TL3 (e.g., see FIG. 6), and the other end of each of the extension trace lines TL-L may be connected to the pads PD.

FIG. 5A illustrates the extension trace lines TL-L disposed between the data lines DL1 to DLn. However, the present disclosure is not limited thereto. For example, the data lines DL1 to DLn may be disposed between the extension trace lines TL-L, and accordingly, the first contact hole CN-H1 may be provided in a plurality to be disposed with the data lines DL1 to DLn therebetween, and is not limited to any particular embodiment.

Referring to FIG. 5B, a third area A3 of a display panel DP according to an embodiment may include a signal line area SGA, data line areas DTL1 and DTL2, power line areas VDL, VSL1, and VSL2, and a trace line area TRL. The signal line area SGA may be defined as an area on which signal lines connected to pixels PX are disposed. The signal lines are not limited to any one particular line, as long as it is connected to the pixels PX and the pads PD.

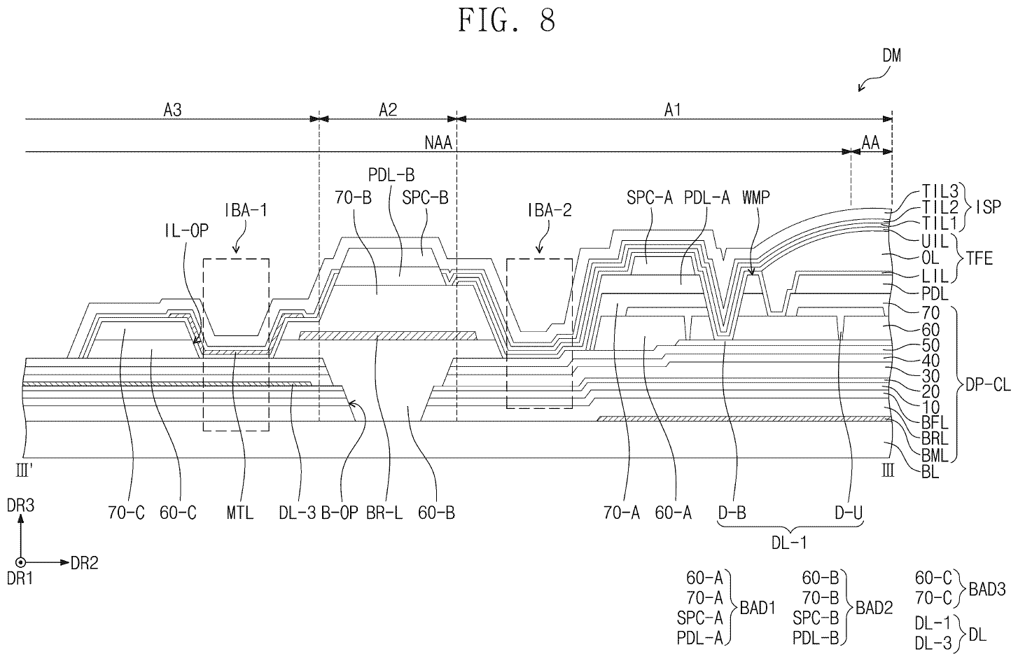

The data line areas DTL1 and DTL2 may be spaced apart from each other. Each of the data line areas DTL1 and DTL2 may be defined as an area of the third area A3 on which the data lines DL1 to DLn (e.g., see FIG. 5A) are disposed. The data lines DL1 to DLn (e.g., see FIG. 5A) may be disposed in the first area A1 and the third area A3. The data lines DL1 to DLn (e.g., see FIG. 5A) may be disconnected in the second area A2. The data lines DL1 to DLn (e.g., see FIG. 5A) disposed in the first area A1 and the data lines DL1 to DLn in the third area A3 may be connected to each other through bridge patterns BR-L (e.g., see FIG. 8) disposed in the second area A2. This will be described in more detail below. One end of each of the data lines DL1 to DLn (e.g., see FIG. 5A) disposed in the third area A3 may be connected to the bridge patterns BR-L (e.g., see FIG. 8), and the other end of each of the data lines DL1 to DLn disposed in the third area A3 may be connected to the driving chip DIC. FIG. 5B illustrates two data line areas DTL1 and DTL2. However, the present disclosure is not limited thereto, and the number of the data line areas disposed in the third area A3 is not limited to any particular number.

According to an embodiment, the lines, which are disposed on the signal line area SGA and the data line areas DTL1 and DTL2 within the third area A3, may be disposed at (e.g., in or on) the same layer as each other.

The power line areas VDL, VSL1, and VSL2 may be spaced apart from each other within the third area A3. The power line areas VDL, VSL1, and VSL2 may be defined as areas on which the power lines PL described above with reference to FIG. 5A are disposed in the third area A3.

A first power line area VDL may be disposed between a (2-1)-th power line area VSL1 and a (2-2)-th power line area VSL2. The first power line area VDL may be an area on which the lines that supply a first voltage to the pixels PX are disposed.

The second power line areas VSL1 and VSL2 may be spaced apart from each other with the first power line area VDL therebetween. The second power line areas VSL1 and VSL2 may supply, to the pixels PX, a second voltage having a lower level than that of the first voltage.

The power lines PL (e.g., see FIG. 5A) may be disposed in the first area A1 and the third area A3. The power lines PL (e.g., see FIG. 5A) may be disconnected in the second area A2. The power lines PL (e.g., see FIG. 5A) disposed in the first area A1 and the power lines PL in the third area A3 may be connected to each other through the bridge patterns BR-L (e.g., see FIG. 8) disposed in the second area A2. This will be described in more detail below. One end of each of the power lines PL (e.g., see FIG. 5A) disposed in the third area A3 may be connected to the bridge patterns BR-L (e.g., see FIG. 8), and the other end of each of the power lines PL (e.g., see FIG. 5A) disposed in the third area A3 may be connected to the pads PD disposed on the pad area PDA.

According to an embodiment, the lines, which are disposed on the data line areas DTL1 and DTL2 within the third area A3, and the lines disposed on the power line areas VDL, VSL1, and VSL2, may be disposed at (e.g., in or on) different layers from each other. Thus, the data line areas DTL1 and DTL2, and the power line areas VDL, VSL1, and VSL2 may overlap with each other in the third area A3 on a plane (e.g., in a plan view).

In the display panel DP according to an embodiment of the present disclosure, insulation layers, which overlap with the second area A2, from among insulation layers included in the display panel DP may be removed to bend (e.g., easily bend) the second area A2. As the insulation layers are removed, moisture may be introduced into a boundary between the second area A2 and the first area A1 and a boundary between the second area A2 and the third area A3.

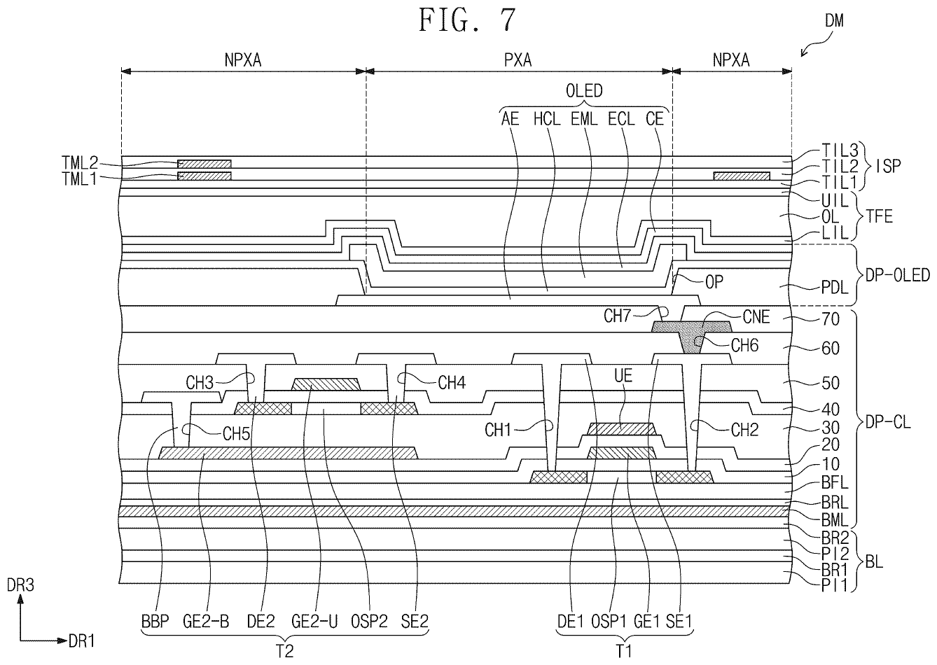

The display panel DP according to an embodiment of the present disclosure may include a bonding area IBA-1 disposed in the third area A3, and adjacent to the boundary between the second area A2 and the third area A3. The bonding area IBA-1 may be defined as an area on which first and second sensing insulation layers TIL1 and TIL2 (e.g., see FIG. 7), each of which includes an inorganic material, from among sensing insulation layers TIL1, TIL2, and TIL3 included in an input sensor ISP to be described in more detail below are disposed. The bonding area IBA-1 may further include a conductive pattern disposed between the first and second sensing insulation layers TIL1 and TIL2 (e.g., see FIG. 7). The conductive pattern may include the same material as that of one of conductive layers included in the input sensor ISP (e.g., see FIG. 7).

According to an embodiment, an additional bonding area IBA-2 may be included that is disposed in the first area A1, and adjacent to the boundary between the first area A1 and the second area A2. The additional bonding area IBA-2 may be defined as an area with which the first and second sensing insulation layers TIL1 and TIL2 (e.g., see FIG. 7), each of which includes an inorganic material, from among the sensing insulation layers TIL1, TIL2, and TIL3 included in the input sensor ISP are in contact.

According to an embodiment of the present disclosure, the bonding area IBA-1 may extend to both ends (e.g., opposite ends) of the third area A3 in the first direction DR1. In addition, the additional bonding area IBA-2 may extend to both ends (e.g., opposite ends) of the first area A1 in the first direction DR1.

According to an embodiment of the present disclosure, the bonding area IBA-1 may have a stacked structure of inorganic layer/conductive pattern/inorganic layer, and the additional bonding area IBA-2 may have a stacked structure of inorganic layer/inorganic layer. Accordingly, paths from the second area A2 to the first area A1 and from the second area A2 to the third area A3, through which moisture may be introduced, may be blocked. Thus, the display panel DP having improved reliability may be provided.

FIG. 6 is a plan view of an input sensor according to an embodiment of the present disclosure.

Referring to FIG. 6, an input sensor ISP according to an embodiment may include sensing electrodes TE1 and TE2 and trace lines TL1, TL2, and TL3. When the input sensor ISP is formed directly on the display panel DP through a continuous process, the sensing electrodes TE1 and TE2 may be provided only on an active area AA overlapping with the first area A1 of the display panel DP.

The input sensor ISP may obtain information of an external input through a variation in a capacitance between first sensing electrodes TE1 and second sensing electrodes TE2. The first sensing electrodes TE1 are arranged along the first direction DR1, and each of the first sensing electrodes TE1 extends in the second direction DR2. Each of the first sensing electrodes TE1 may include first sensing patterns SP1 and first connection patterns CP1.

The first sensing patterns SP1 are disposed in the active area AA. The first sensing patterns SP1 included in one first sensing electrode TE1 may be arranged along the second direction DR2. Each of the first sensing patterns SP1 may have a rhombic shape. However, the present disclosure is not limited thereto. The first sensing patterns SP1 may have various suitable shapes, and are not limited to any particular shape.

The first connection pattern CP1 is disposed in the active area AA. The first connection pattern CP1 may be disposed between the first sensing patterns SP1 that are adjacent thereto in the second direction DR2. The first connection pattern CP1 may be disposed at (e.g., in or on) a different layer from that of the first sensing pattern SP1 to be connected to the first sensing pattern SP1 through a contact hole.

The second sensing electrodes TE2 are arranged along the second direction DR2, and each of the second sensing electrodes TE2 extends in the first direction DR1. Each of the second sensing electrodes TE2 may include second sensing patterns SP2 and second connection patterns CP2.

The second sensing patterns SP2 may be spaced apart from the first sensing patterns SP1. The first sensing patterns SP1 and the second sensing patterns SP2 may be in non-contact with (e.g., may not contact) each other to transmit/receive independent electrical signals from each other.

The second sensing patterns SP2 are disposed in the active area AA. The second sensing patterns SP2 included in one second sensing electrode TE2 may be arranged along the first direction DR1. The second sensing patterns SP2 may have the same shape as that of the first sensing pattern SP1. For example, each of the second sensing patterns SP2 may have a rhombic shape. However, the present disclosure is not limited thereto. The second sensing patterns SP2 may have various suitable shapes, and are not limited to any particular shape.

The second connection pattern CP2 may be disposed between the second sensing patterns SP2 that are adjacent thereto. The second sensing patterns SP2 and the second connection pattern CP2, which are included in one second sensing electrode TE2, may have substantially one-body shape and/or one-body pattern.

According to an embodiment, the first sensing patterns SP1, the second sensing patterns SP2, and the second connection patterns CP2 may be disposed at (e.g., in or on) the same layer as each other, and the first connection patterns CP1 may be disposed at (e.g., in or on) a different layer therefrom. The first sensing patterns SP1, the second sensing patterns SP2, and the second connection patterns CP2 may be provided as a plurality of mesh lines extending in a direction diagonal to each of the first direction DR1 and the second direction DR2.

The trace lines TL1, TL2, and TL3 are disposed on the peripheral area NAA. The trace lines TL1, TL2, and TL3 may include first trace lines TL1, second trace lines TL2, and third trace lines TL3.

One end of each of the first trace lines TL1 may be connected to the first sensing electrodes TE1. In the present embodiment, the first trace lines TL1 may be connected to lower ends, respectively, from among both sides (e.g., opposite sides) of the first sensing electrodes TE1. One end of the second trace lines TL2 may be connected to upper ends, respectively, from among both sides (e.g., opposite sides) of the first sensing electrodes TE1. According to an embodiment of the present disclosure, one first sensing electrode TE1 may be connected to the first trace line TL1 and the second trace line TL2. Accordingly, sensitivity according to areas may be uniformly or substantially uniformly maintained with respect to the first sensing electrode TE1, each having a relatively greater length than that of the second sensing electrodes TE2.

However, the present disclosure is not limited thereto. For example, in the input sensor ISP according to an embodiment of the present disclosure, one of the first trace lines TL1 and/or the second trace lines TL2 may be omitted as needed or desired, and the input sensor ISP is not limited to any particular embodiment.

One end of each of the third trace lines TL3 may be connected to the second sensing electrodes TE2. In the present embodiment, the third trace lines TL3 may be connected to left ends, respectively, from among both sides (e.g., opposite sides) of the second sensing electrodes TE2.

A second contact hole CN-H2 defined by passing through at least one of the insulation layers included in the input sensor ISP may be defined in the input sensor ISP. The second contact hole CN-H2 may overlap with the first contact hole CN-H1 defined in the first area A1 of the display panel DP.

The other end of each of the trace lines TL1, TL2, and TL3 may be disposed in the second contact hole CN-H2. The other end of each of the trace lines TL1, TL2, and TL3 disposed in the second contact hole CN-H2 may be connected to the extension trace lines TL-L (e.g., see FIG. 5). The trace lines TL1, TL2, and TL3 may be connected to the pads PD (e.g., see FIG. 5) through the extension trace lines TL-L disposed in the display panel DP (e.g., see FIG. 5).

FIG. 7 is a cross-sectional view of a display module according to an embodiment of the present disclosure.

FIG. 7 illustrates a cross-section corresponding to a first transistor T1, a second transistor T2, and a light emitting element OLED, which are some of the components of the pixel PX (e.g., see FIG. 5).

The display panel DP may include a base layer BL. The display panel DP may further include a circuit element layer DP-CL, a display element layer DP-OLED, and an encapsulation layer TFE disposed on the base layer BL. The display panel DP may further include functional layers, such as an anti-reflection layer and a refractive index adjusting layer. The circuit element layer DP-CL includes at least a plurality of insulation layers and a circuit element. The insulation layers may include an organic layer and/or an inorganic layer.

The circuit element includes a signal line, a driving circuit of a pixel, and the like. The circuit element layer DP-CL may be formed through a process of forming an insulation layer, a semiconductor layer, and a conductive layer through coating, deposition, or the like, and a process of patterning the insulation layer, the semiconductor layer, and the conductive layer through photolithography. The display element layer DP-OLED may include the light emitting element OLED and a pixel defining layer PDL.

The base layer BL may include a synthetic resin film. A synthetic resin layer may include a thermosetting resin. In more detail, the synthetic resin layer may be a polyimide-based resin layer, but the material thereof is not particularly limited thereto. The synthetic resin layer may include at least one of acrylic resin, an methacryl-based resin, polyisoprene, a vinyl-based resin, an epoxy-based resin, a urethane-based resin, a cellulose-based resin, a siloxane-based resin, a polyamide-based resin, or a perylene-based resin. In addition, the base layer BL may include a glass substrate, a metal substrate, an organic/inorganic composite substrate, or the like.

The base layer BL according to an embodiment may include a first base layer PI1, a first cover layer BR1, a second base layer PI2, and a second cover layer BR2, which are stacked sequentially or in sequence in the third direction DR3.

The first base layer PI1 may be disposed at the lowest side. The first base layer PI1 may include an organic material. For example, the first base layer PI1 may include one of polyimide (PI), polyethylene naphthalate (PEN), polyethylene terephthalate (PET), polyarylate, polycarbonate (PC), polyetherimide (PEI), and/or polyethersulfone (PES).

The first cover layer BR1 may be disposed on the first base layer PI1. The first cover layer BR1 may include an inorganic material. For example, the first cover layer BR1 may include at least one of silicon oxide, silicon oxynitride, aluminum oxide, titanium oxide, silicon nitride, zirconium oxide, hafnium oxide, or amorphous silicon.

The second base layer PI2 may be disposed on the first cover layer BR1. The second base layer PI2 may include an organic material. The organic material included in the second base layer PI2 may be the same or substantially the same as the organic material included in the first base layer PI1.

The second cover layer BR2 may be disposed on the second base layer PI2. The second cover layer BR2 may include an inorganic material. The inorganic material included in the second cover layer BR2 may be the same or substantially the same as the inorganic material included in the first cover layer BR1.

A light blocking pattern BML may be disposed on the second cover layer BR2. The light blocking pattern BML may prevent or substantially prevent an electrical potential caused by a polarization phenomenon from affecting the first transistor T1. The light blocking pattern BML may prevent or substantially prevent external light from reaching the first transistor T1. In an embodiment of the present disclosure, the light blocking pattern BML may be a floating electrode that is isolated from another electrode or a line. The light blocking pattern BML may include molybdenum.

A barrier layer BRL may be disposed on the light blocking pattern BML. The barrier layer BRL prevents or substantially prevents foreign matters from being introduced from the outside. The barrier layer BRL may include a silicon oxide layer and a silicon nitride layer. Each of the silicon oxide layer and the silicon nitride layer may be provided in a plurality, and the silicon oxide layers and the silicon nitride layers may be stacked alternately on one another.

A buffer layer BFL may be disposed on the barrier layer BRL. The buffer layer BFL improves a bonding force between the base layer BL and conductive patterns or semiconductor patterns. The buffer layer BFL may include a silicon oxide layer and a silicon nitride layer. The silicon oxide layer and the silicon nitride layer may be alternately stacked on one another.

A first semiconductor pattern OSP1 is disposed on the buffer layer BFL. The first semiconductor pattern OSP1 may include a silicon semiconductor. The first semiconductor pattern OSP1 may be a polycrystalline silicon semiconductor. However, the present disclosure is not limited thereto, and the first semiconductor pattern OSP1 may include amorphous silicon.

The first semiconductor pattern OSP1 may include an input region (e.g., a first portion), an output region (e.g., a second portion), and a channel region (e.g., a third portion) defined between the input region and the output region. The channel region of the first semiconductor pattern OSP1 may be defined to correspond to a first control electrode GE1 to be described in more detail below. The input region and the output region may be doped with dopants to have a relatively higher conductivity compared to that of the channel region. The input region and the output region may be doped with n-type dopants. In the present embodiment, an n-type first transistor T1 is illustrated as an example, but the present disclosure is not limited thereto, and the first transistor T1 may be a p-type transistor.

A first insulation layer 10 is disposed on the buffer layer BFL. The first insulation layer 10 overlaps with the plurality of pixels PX (e.g., see FIG. 2) in common, and covers the first semiconductor pattern OSP1. The first insulation layer 10 may be an inorganic layer and/or an organic layer, and may have a single-layer structure or a multilayered structure. The first insulation layer 10 may include at least one of aluminum oxide, titanium oxide, silicon oxide, silicon oxynitride, zirconium oxide, or hafnium oxide. In the present embodiment, the first insulation layer 10 may be a silicon oxide layer having a single-layer structure.

The first control electrode GE1 is disposed on the first insulation layer 10. The first control electrode GE1 overlaps with the channel region of the first semiconductor pattern OSP1.

A second insulation layer 20 that covers the first control electrode GE1 is disposed on the fifth insulation layer 10. The second insulation layer 20 overlaps with the plurality of pixels PX (e.g., see FIG. 1) in common. The second insulation layer 20 may be an inorganic layer and/or an organic layer, and may have a single-layer structure or a multilayered structure. The second insulation layer 20 may include at least one of aluminum oxide, titanium oxide, silicon oxide, silicon oxynitride, zirconium oxide, or hafnium oxide. In the present embodiment, the second insulation layer 20 may be a silicon oxide layer having a single-layer structure.

An upper electrode UE may be further disposed on the second insulation layer 20. The upper electrode UE may overlap with the first control electrode GE1.

A lower control electrode GE2-B of the second transistor T2 may be further disposed on the second insulation layer 20. The lower control electrode GE2-B may overlap with a second semiconductor pattern OSP2. The lower control electrode GE2-B may provide a double-gate together with an upper control electrode GE2-U.

A third insulation layer 30 that covers the upper electrode UE and the lower control electrode GE2-B is disposed on the second insulation layer 20. The third insulation layer 30 may be an inorganic layer and/or an organic layer, and may have a single-layer structure or a multilayered structure. The third insulation layer 30 may include at least one of aluminum oxide, titanium oxide, silicon oxide, silicon oxynitride, zirconium oxide, or hafnium oxide. In the present embodiment, the third insulation layer 30 may be a silicon oxide layer having a single-layer structure.

The second semiconductor pattern OSP2 is disposed on the third insulation layer 30. The second semiconductor pattern OSP2 may include an oxide semiconductor. The second semiconductor pattern OSP2 may include a crystalline or amorphous oxide semiconductor. For example, the oxide semiconductor may include a metal oxide of zinc (Zn), indium (In), gallium (Ga), tin (Sn), titanium (Ti), or the like, or may include a mixture of a metal, such as zinc (Zn), indium (In), gallium (Ga), tin (Sn), or titanium (Ti), and an oxide thereof. The oxide semiconductor may include indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), or the like.

The second semiconductor pattern OSP2 may include an input region (e.g., a first portion), an output region (e.g., a second portion), and a channel region (e.g., a third portion) defined between the input region and the output region. The input region and the output region may include impurities. The channel region of the second semiconductor pattern OSP2 may be defined to correspond to the upper control electrode GE2-U to be described in more detail below.

The impurities of the second semiconductor pattern OSP2 may be reduced metal materials. The input region and the output region may include metal materials reduced from the metal oxide of which the channel region is made. Accordingly, the second transistor T2 may reduce a leakage current to function as a switching element having improved on-off characteristics.

A fourth insulation layer 40 that covers the second semiconductor pattern OSP2 is disposed on the third insulation layer 30. The fourth insulation layer 40 may be an inorganic layer and/or an organic layer, and may have a single-layer structure or a multilayered structure. The fourth insulation layer 40 may include at least one of aluminum oxide, titanium oxide, silicon oxide, silicon oxynitride, zirconium oxide, or hafnium oxide.

The upper control electrode GE2-U is disposed on the fourth insulation layer 40. The upper control electrode GE2-U overlaps with the second semiconductor pattern OSP2.

A fifth insulation layer 50 that covers the upper control electrode GE2-U is disposed on the fourth insulation layer 40. The fifth insulation layer 50 may be an inorganic layer and/or an organic layer, and may have a single-layer structure or a multilayered structure. The fifth insulation layer 50 may include at least one of aluminum oxide, titanium oxide, silicon oxide, silicon oxynitride, zirconium oxide, or hafnium oxide.

A first input electrode DE1, a first output electrode SE1, a second input electrode DE2, and a second output electrode SE2 are disposed on the fifth insulation layer 50. The first input electrode DE1 and the first output electrode SE1 are connected to the first semiconductor pattern OSP1 through a first contact hole CH1 and a second contact hole CH2, respectively, which expose the input region and the output region of the first semiconductor pattern OSP1. The first contact hole CH1 and the second contact hole CH2 pass through the first insulation layer 10 to the fifth insulation layer 50.

The second input electrode DE2 and the second electrode SE2 are connected to the second semiconductor pattern OSP2 through a third contact hole CH3 and a fourth contact hole CH4, respectively, which expose the input region and the output region of the second semiconductor pattern OSP2. The third contact hole CH3 and the fourth contact hole CH4 pass through the fifth insulation layer 50.

The display panel DP according to an embodiment may further include a control bridge pattern BBP disposed on the fourth insulation layer 40. The control bridge pattern BBP may be branched from a portion of the upper control electrode GE2-U. The control bridge pattern BBP may be connected to the lower control electrode GE2-B through a fifth contact hole CH5. The fifth contact hole CH5 passes through the third insulation layer 30 and the fourth insulation layer 40.

A sixth insulation layer 60, which covers the first input electrode DE1, the first output electrode SE1, the second input electrode DE2, and the second output electrode SE2, is disposed on the fifth insulation layer 50. The sixth insulation layer 60 may be an organic layer, and may have a single-layer structure or a multilayered structure.

An connection electrode CNE is disposed on the sixth insulation layer 60. The connection electrode CNE may be connected to the first output electrode SE1 through a sixth contact hole CH6 passing through the sixth insulation layer 60.

A seventh insulation layer 70 (e.g., a passivation layer) that covers the connection electrode CNE is disposed on the sixth insulation layer 60. The seventh insulation layer 70 may be an organic layer, and may have a single-layer structure or a multilayered structure.

In the present embodiment, each of the sixth insulation layer 60 and the seventh insulation layer 70 may be a polyimide-based resin layer having a single-layer structure. However, the present disclosure is not limited thereto, and each of the sixth insulation layer 60 and the seventh insulation layer 70 may include at least one of an acrylic resin, a methacryl-based resin, polyisoprene, a vinyl-based resin, an epoxy-based resin, a urethane-based resin, a cellulose-based resin, a siloxane-based resin, a polyamide-based resin, or a perylene-based resin.

The light emitting element OLED is disposed on the seventh insulation layer 70. An anode AE of the light emitting element OLED is disposed on the seventh insulation layer 70. The anode AE is connected to the connection electrode CNE through a seventh contact hole CH7 passing through the seventh insulation layer 70. A pixel defining layer PDL is disposed on the seventh insulation layer 70.

An opening portion OP of the pixel defining layer PDL exposes at least a portion of the anode AE. The opening portion OP of the pixel defining layer PDL may define an emissive area PXA of a pixel. For example, the plurality of pixels PX (e.g., see FIG. 2) may be disposed in the display panel DP according to a suitable rule (e.g., a certain or predetermined rule) on a plane (e.g., in a plan view). An area on which the plurality of pixels PX are disposed may correspond to the active area AA described above with reference to FIG. 5A, and the active area AA may include the emissive areas PXA and a non-emissive area NPXA adjacent to the emissive areas PXA. The non-emissive area NPXA may surround (e.g., around peripheries of) the emissive areas PXA.

A hole control layer HCL may be disposed in the emissive areas PXA and the non-emissive area NPXA in common. A common layer, such as the hole control layer HCL, may be provided in common in the plurality of pixels PX (e.g., see FIG. 2). The hole control layer HCL may include a hole transport layer and/or a hole injection layer.

An organic light emitting layer EML is disposed on the hole control layer HCL. The organic light emitting layer EML may be disposed in an area (e.g., only in an area) corresponding to the opening portion OP. The organic light emitting layer EML may be separately provided for each of the plurality of pixels PX (e.g., see FIG. 2).

In the present embodiment, the patterned organic light emitting layer EML is illustrated as an example, but the organic light emitting layer EML may be disposed in common in the plurality of pixels PX. In this case, the organic light emitting layer EML may generate light having a white color. In addition, the organic light emitting layer EML may have a multilayered structure.

An electron control layer ECL is disposed on the organic light emitting layer EML. The electron control layer ECL may include an electron transport layer and/or an electron injection layer. A cathode CE is disposed on the electron control layer ECL. The electron control layer ECL and the cathode CE are disposed in common in the plurality of pixels PX (e.g., see FIG. 2).

The encapsulation layer TFE is disposed on the cathode CE. The encapsulation layer TFE is disposed in common in the plurality of pixels PX. In the present embodiment, the encapsulation layer TFE directly covers the cathode CE. The encapsulation layer TFE may cover the light emitting element OLED. The encapsulation layer TFE may include two inorganic encapsulation layers LIL and UIL, and an organic encapsulation layer OL disposed between the inorganic encapsulation layers LIL and UIL. In an embodiment of the present disclosure, the encapsulation layer TFE may include a plurality of inorganic layers and a plurality of organic layers, which are alternately stacked on one another.

The inorganic encapsulation layers LIL and UIL protect the light emitting element OLED against moisture/oxygen, and the organic encapsulation layer OL protects the light emitting element OLED against foreign matters, such as dust particles. The inorganic encapsulation layers LIL and UIL may include a silicon nitride layer, a silicon oxynitride layer, a silicon oxide layer, a titanium oxide layer, or an aluminum oxide layer, but the present disclosure is not particularly limited thereto. The organic encapsulation layer OL may include an acrylic organic layer, but the present disclosure is not particularly limited thereto.

According to the present embodiment, as the first transistor T1 includes a silicon semiconductor, such as a polycrystalline silicon semiconductor, the first transistor T1 may have a higher electron mobility. As the second transistor T2 includes an oxide semiconductor, a leakage current may be reduced. Thus, a driving voltage of the pixels PX (e.g., see FIG. 2) may be reduced, and malfunctioning of the pixels PX may be prevented or substantially prevented.

An input sensor ISP may be further disposed directly on the display panel DP. The input sensor ISP may include sensing insulation layers TIL1, TIL2, and TIL3, and one or more conductive layers TML1 and TML2. Each of the sensing insulation layers TIL1, TIL2, and TIL3 may include one of an inorganic matter and/or an organic matter.

A first sensing insulation layer TIL1 may be disposed directly on the second inorganic layer UIL of the encapsulation layer TFE. A first conductive layer TML1 is disposed on the first sensing insulation layer TIL1. A second sensing insulation layer TIL2 may be disposed on the first sensing insulation layer TIL1, and may cover the first conductive layer TML1. A second conductive layer TML2 is disposed on the second sensing insulation layer TIL2. A third sensing insulation layer TIL3 may be disposed on the second sensing insulation layer TIL2, and may cover the second conductive layer TML2. However, the present disclosure is not limited thereto. For example, the first sensing insulation layer TIL1 may be omitted as needed or desired, and the first conductive layer TML1 may be disposed directly on the second inorganic layer UIL, but the present disclosure is not limited to any particular embodiment.

According to an embodiment of the present disclosure, each of the first and second sensing insulation layers TIL1 and TIL2 may include an inorganic material, and the third sensing insulation layer TIL3 may include an organic material.

The first connection patterns CP1 of the sensing electrodes TE1 and TE2 described above with reference to FIG. 6 may be included in the first conductive layer TML1. The first sensing patterns SP1, the second sensing patterns SP2, and the second connection patterns CP2 may be included in the second conductive layer TML2. Thus, the adjacent first sensing patterns SP1 may be connected to the first connection pattern CP1 through a contact hole defined in the second sensing insulation layer TIL2.

FIG. 8 is a cross-sectional view taken along the line III-III′ in FIG. 5B. FIG. 8 illustrates a cross-section from an additional bonding area IBA-2 of the first area A1 via the second area A2 to a bonding area IBA-1 of the third area A3.

Referring to FIG. 8, according to an embodiment, a data line DL may be disposed in the first area A1 and the third area A3, and may be disconnected in the second area A2. A data line DL-1 disposed in the first area A1 may include a lower line D-B disposed on the fifth insulation layer 50, and an upper line D-U disposed on the sixth insulation layer 60. The upper line D-U may be connected to the lower line D-B through a contact hole passing through the sixth insulation layer 60. However, the present disclosure is not limited thereto. For example, the data line DL-1 disposed in the first area A1 may be provided as a single layer in which one of the lower line D-B or the upper line D-U is omitted. A data line DL-3 disposed in the third area A3 may be disposed on the second insulation layer 20. The data line DL-3 disposed in the third area A3 may be connected to the driving chip DIC as described above with reference to FIG. 5B.

The data line DL-1 disposed in the first area A1 and the data line DL-3 disposed in the third area A3 may be connected to each other through a bridge pattern BR-L disposed in the second area A2. The upper line D-U disposed in the first area A1 may be disposed at (e.g., in or on) the same layer as that of one end of the bridge pattern BR-L, and thus, may be directly connected to each other. The other end of the bridge pattern BR-L may be connected to the data line DL-3 disposed in the third area A3 through a contact hole passing through the third to sixth insulation layers 30, 40, 50, and 60.

According to the present embodiment, a boundary of the organic encapsulation layer OL included in the encapsulation layer TFE within the first area A1 may be defined by a dam pattern WMP. The dam pattern WMP may be provided in a multilayered structure. For example, a lower layer may include the same material as that of the sixth insulation layer 60, and an upper layer may include the same material as that of the seventh insulation layer 70. FIG. 8 illustrates one dam pattern WMP that is disposed in the peripheral area NAA of the first area A1, but the number of the dam pattern WMP is not limited thereto.

A first structure BAD1 may be disposed in the first area A1. The first structure BAD1 may be disposed between the dam pattern WMP and the second area A2. The first structure BAD1 may include a first pattern 60-A including the same material as that of the sixth insulation layer 60, a second pattern 70-A including the same material as that of the seventh insulation layer 70, a third pattern PDL-A including the same material as that of the pixel defining layer PDL, and a fourth pattern SPC-A disposed on the third pattern PDL-A. The fourth pattern SPC-A may include an organic material. Thus, the first structure BAD1 may be a structure in which the layers, each including an organic material, are stacked on one another.

According to the present embodiment, an opening portion B-OP passing through the barrier layer BRL, the buffer layer BFL, and the first to fifth insulation layers 10, 20, 30, 40, and 50 to expose the base layer BL may be defined in the second area A2. A second structure BAD2 may be disposed in the opening portion B-OP. The second structure BAD2 may include a first pattern 60-B including the same material as that of the sixth insulation layer 60, a second pattern 70-B including the same material as that of the seventh insulation layer 70, a third pattern PDL-B including the same material as that of the pixel defining layer PDL, and a fourth pattern SPC-B disposed on the third pattern PDL-B. The fourth pattern SPC-B may include an organic material. Thus, the second structure BAD2 may be a structure in which the layers, each including an organic material, are stacked on one another.

According to an embodiment of the present disclosure, the additional bonding area IBA-2 may be defined between the second area A2 and the first structure BAD1. The barrier layer BRL, the buffer layer BFL, the first to fifth insulation layers 10, 20, 30, 40, and 50, the inorganic layers LIL and UIL, and the first and second sensing insulation layers TIL1 and TIL2 may be disposed in the additional bonding area IBA-2. The third sensing insulation layer TIL3 may cover the second sensing insulation layer TIL2. The sixth and seventh insulation layers 60 and 70, each including an organic material, may be omitted (e.g., may not be disposed) in the additional bonding area IBA-2. The inorganic layers LIL and UIL and the first and second sensing insulation layers TIL1 and TIL2, which are disposed in the additional bonding area IBA-2, may be in contact with each other to block a path through which moisture may be introduced in a direction from the second area A2 toward the first area A1.

A third structure BAD3 may be disposed in the third area A3. The third structure BAD3 may include a first pattern 60-C including the same material as that of the sixth insulation layer 60, and a second pattern 70-C including the same material as that of the seventh insulation layer 70. Thus, the third structure BAD3 may be a structure in which the layers, each including an organic material, are stacked on each other.

According to an embodiment of the present disclosure, the bonding area IBA-1 may be defined between the second area A2 and the third structure BAD3. The barrier layer BRL, the buffer layer BFL, the first to fifth insulation layers 10, 20, 30, 40, and 50, and the first and second sensing insulation layers TIL1 and TIL2 may be disposed in the bonding area IBA-1. The inorganic layers LIL and UIL may not be disposed in the bonding area IBA-1. The third sensing insulation layer TIL3 may cover the second sensing insulation layer TIL2.

According to an embodiment, an opening portion IL-OP overlapping with the bonding area IBA-1 may be defined in the sixth and seventh insulation layers 60 and 70. The opening portion IL-OP may expose the fifth insulation layer 50. In more detail, the opening portion IL-OP may be defined between the first and second patterns 60-B and 70-B of the second structure BAD2 and the first and second patterns 60-C and 70-C of the third structure BAD3.

According to an embodiment of the present disclosure, a conductive pattern MTL may be further disposed in the bonding area IBA-1 of the third area A3. The conductive pattern MTL may be disposed between the first sensing insulation layer TIL1 and the second sensing insulation layer TIL2 within the bonding area IBA-1, and may be in contact with the first sensing insulation layer TIL1 and the second sensing insulation layer TIL2. The first and second sensing insulation layers TIL1 and TIL2 and the conductive pattern MTL, which are disposed in the bonding area IBA-1, may be disposed in the opening portion IL-OP. The conductive pattern MTL may be provided in a plurality within the bonding area IBA-1. The plurality of conductive patterns MTL may be spaced apart from each other along the first direction DR1, and each of the conductive patterns MTL may extend in the second direction DR2.

The conductive patterns MTL may have different functions for each area. For example, the conductive pattern MTL disposed on a cross-section of the data line areas DTL1 and DTL2 described above with reference to FIG. 5B and the bonding area IBA-1 may be in a floating state. As another example, one end of the conductive pattern MTL disposed on the cross-section of the power line areas VDL, VSL1, and VSL2 described above with reference to FIG. 5B and the bonding area IBA-1 may be connected to the bridge pattern BR-L, and the other end of the conductive pattern MTL may be connected to a power line disposed in the power line areas VDL, VSL1, and VSL2.

The conductive pattern MTL may include the same material as that of the first and second conductive layers TML1 and TML2 described above with reference to FIG. 7. The first and second conductive layers TML1 and TML2 and the conductive pattern MTL may include first to third layers that are stacked in sequence (e.g., that are sequentially stacked). The first and third layers may include titanium, and the second layer may include aluminum.

According to the present embodiment, the first and second sensing insulation layers TIL1 and TIL2 and the conductive pattern MTL, which are disposed in the bonding area IBA-1, may be in contact with each other to block a path through which moisture may be introduced in a direction from the second area A2 toward the third area A3. Thus, the display panel DP having improved reliability may be provided.

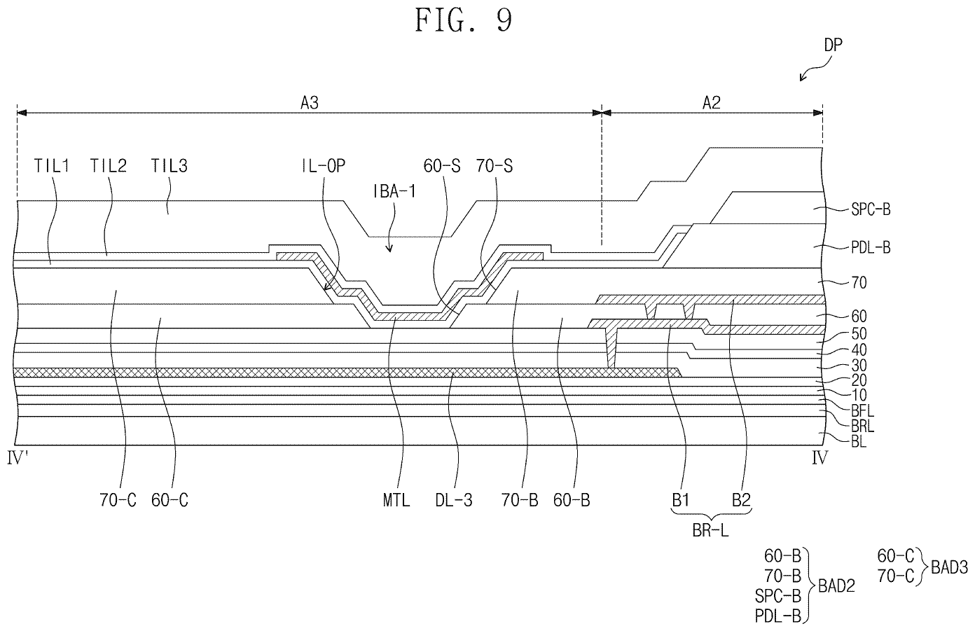

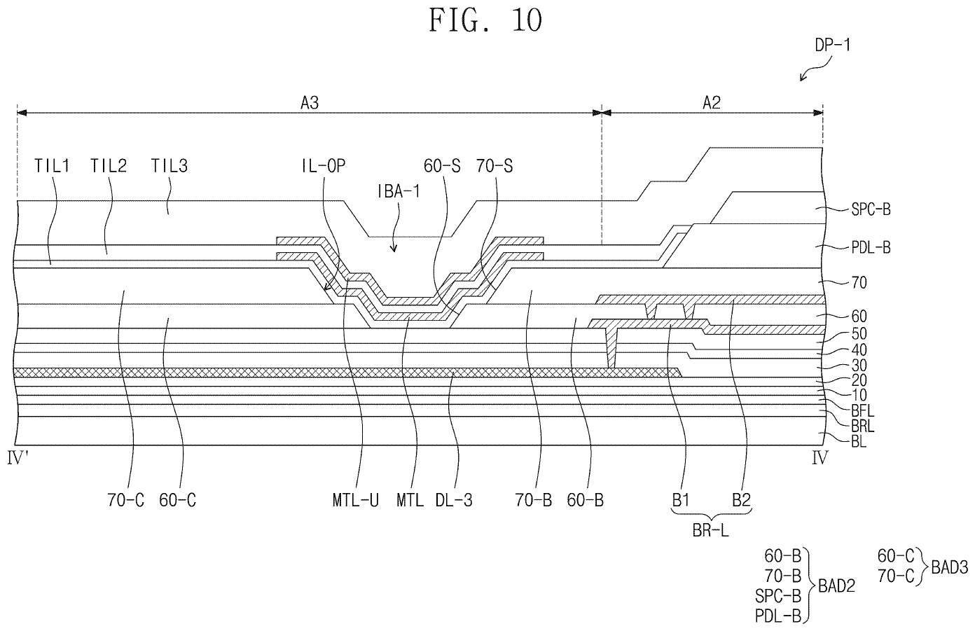

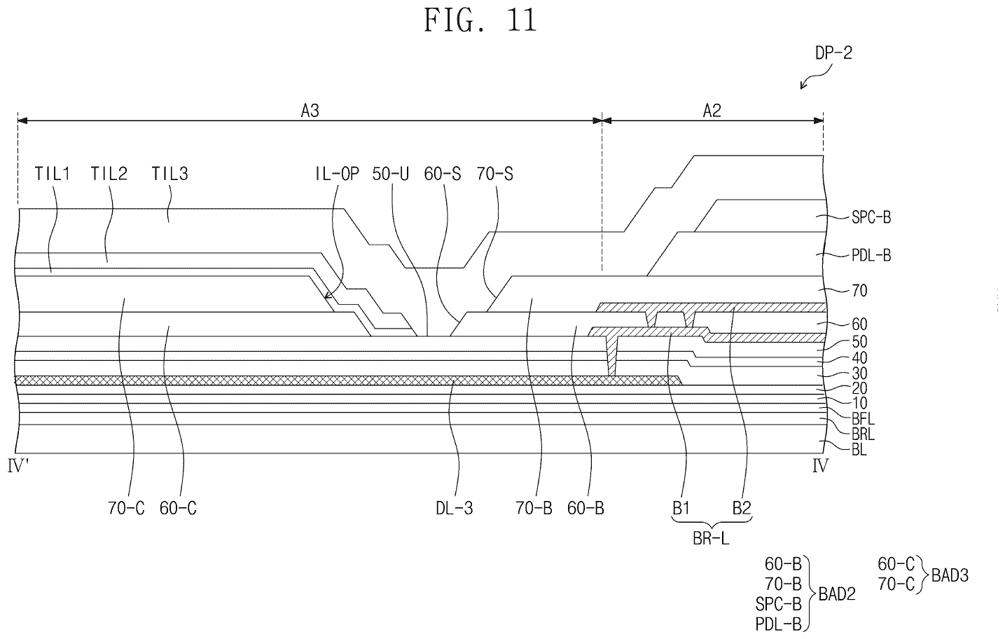

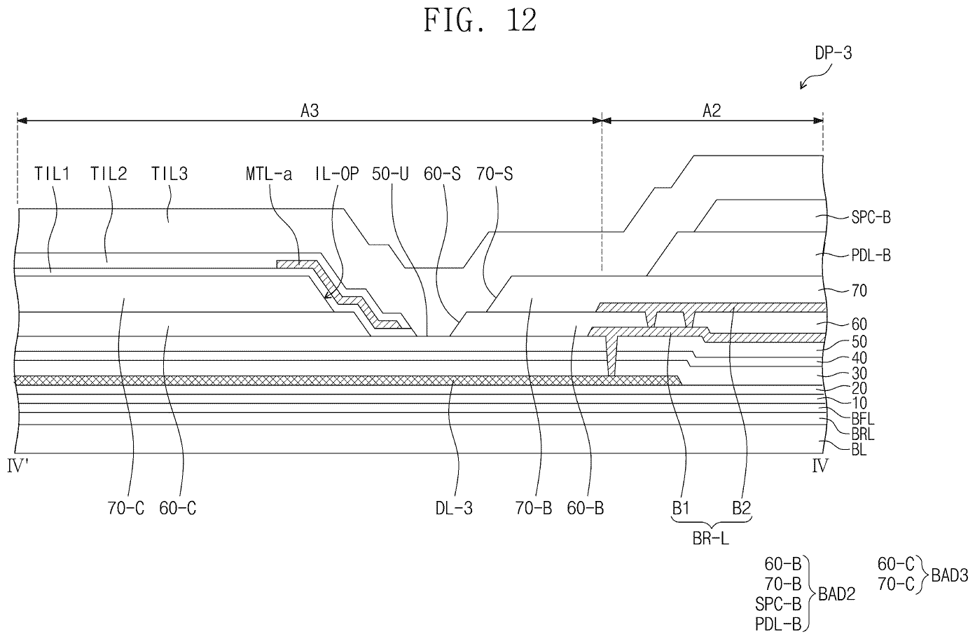

FIG. 9 is a cross-sectional view taken along the line IV-IV′ in FIG. 5B. FIG. 10 is a cross-sectional view of a bonding area of a display panel according to an embodiment of the present disclosure. FIG. 11 is a cross-sectional view of a bonding area of a display panel according to an embodiment of the present disclosure. FIG. 12 is a cross-sectional view of a bonding area of a display panel according to an embodiment of the present disclosure. For example, FIGS. 9 to 12 are cross-sectional views taken along the line IV-IV′ in FIG. 5B. In more detail, FIGS. 9 to 12 are cross-sectional views of a bonding area IBA-1 adjacent to the second area A2 and the data line areas DTL1 and DTL2. The same/similar components as/to those described above with reference to FIG. 8 are designated by the same/similar reference numbers or symbols, and thus, redundant description thereof may not be repeated.

Referring to FIG. 9, a display panel DP according to an embodiment may include a bridge pattern BR-L disposed in the second area A2. The bridge pattern BR-L may include a lower layer B1 and an upper layer B2. The lower layer B1 may be disposed on the fifth insulation layer 50, and may be covered by the sixth insulation layer 60. The upper layer B2 may be disposed on the sixth insulation layer 60, and may be covered by the seventh insulation layer 70. The upper layer B2 may be connected to the lower layer B1 through contact holes passing through the sixth insulation layer 60.

The upper layer B2 may be connected to the data line DL-1 (e.g., see FIG. 8) disposed on the sixth insulation layer 60 of the first area A1. The lower layer B1 may be connected to the data line DL-3 disposed in the third area A3 through a contact hole passing through the third to fifth insulation layers 30, 40, and 50. The data line DL-3 disposed in the third area A3 may be disposed on the second insulation layer 20, and may be covered by the third insulation layer 30.

A bonding area IBA-1 adjacent to a boundary of the second area A2 may be defined in the third area A3. The barrier layer BRL, the buffer layer BFL, the first to fifth insulation layers 10, 20, 30, 40, and 50, the first to third sensing insulation layers TIL1, TIL2, and TIL3, and the conductive pattern MTL may be disposed in the bonding area IBA-1.

According to an embodiment, the opening portion IL-OP overlapping with the bonding area IBA-1 may be defined in the sixth and seventh insulation layers 60 and 70. The opening portion IL-OP may expose the fifth insulation layer 50. In more detail, the opening portion IL-OP may be defined between first and second patterns 60-B and 70-B of a second structure BAD2 and first and second patterns 60-C and 70-C of a third structure BAD3.

The first sensing insulation layer TIL1 may be in contact with a side surface 60-S of a first pattern and a side surface 70-S of a second pattern, each of which defines the opening portion IL-OP, and a portion, which is exposed by the opening portion IL-OP, of the fifth insulation layer 50.

The conductive pattern MTL may be disposed on the first sensing insulation layer TIL1 within the opening portion IL-OP, and may be covered by the second sensing insulation layer TIL2. The third sensing insulation layer TIL3 may cover the second sensing insulation layer TIL2. In the present embodiment, the conductive pattern MTL may be in a floating state.

According to an embodiment, a fourth pattern SPC-B of the second structure BAD2 may be exposed from the first sensing insulation layer TIL1 and the second sensing insulation layer TIL2, and may be covered by the third sensing insulation layer TIL3.

Hereinafter, a display panel DP-1 illustrated in FIG. 10 will be described in more detail by focusing on the differences from the display panel DP described above with reference to FIG. 9. Referring to FIG. 10, the display panel DP-1 according to an embodiment may further include an upper conductive pattern MTL-U. The upper conductive pattern MTL-U may be disposed on the second sensing insulation layer TIL2 within the bonding area IBA-1, and may be covered by the third sensing insulation layer TIL3. The upper conductive pattern MTL-U may overlap with the conductive pattern MTL.

According to the present embodiment, the barrier layer BRL, the buffer layer BFL, the first to fifth insulation layers 10, 20, 30, 40, and 50, the first to third sensing insulation layers TIL1, TIL2, and TIL3, the conductive pattern MTL, and the upper conductive pattern MTL-U may be disposed in the bonding area IBA-1.

The upper conductive pattern MTL-U and the conductive pattern MTL may be in a floating state. According to an embodiment, the upper conductive pattern MTL-U may be connected to the conductive pattern MTL through a contact hole passing through the second sensing insulation layer TIL2.

The conductive pattern MTL may be patterned through the same process as that of the first conductive layer TML1 described above with reference to FIG. 5A, and the upper conductive pattern MTL-U may be patterned through the same process as that of the second conductive layer TML2 described above with reference to FIG. 5A. Thus, the conductive pattern MTL and the upper conductive pattern MTL-U may include the same material as those of the first and second conductive layers TML1 and TML2, respectively.

Referring to FIG. 11, the barrier layer BRL, the buffer layer BFL, the first to fifth insulation layers 10, 20, 30, 40, and 50, and the first to third sensing insulation layers TIL1, TIL2, and TIL3 may be disposed in a bonding area IBA-1 of a display panel DP-2 according to an embodiment.

According to an embodiment, the opening portion IL-OP overlapping with the bonding area IBA-1 may be defined in the sixth and seventh insulation layers 60 and 70. The opening portion IL-OP may expose the fifth insulation layer 50. In more detail, the opening portion IL-OP may be defined between the first and second patterns 60-B and 70-B of the second structure BAD2 and the first and second patterns 60-C and 70-C of the third structure BAD3.

According to the present embodiment, the first sensing insulation layer TIL1 and the second sensing insulation layer TIL2 may expose a side surface 60-S of the sixth insulation layer 60 and a side surface 70-S of the seventh insulation layer 70, each of which is adjacent to the second area A2 and defines the opening portion IL-OP, and a top surface 50-U, which is exposed by the opening portion IL-OP, of the fifth insulation layer 50. The portions exposed by the first sensing insulation layer TIL1 and the second sensing insulation layer TIL2 may be covered by the third sensing insulation layer TIL3.

A display panel DP-3 illustrated in FIG. 12 will be described in more detail hereinafter by focusing on the differences from the display panel DP-2 described above with reference to FIG. 11.

Referring to FIG. 12, the barrier layer BRL, the buffer layer BFL, the first to fifth insulation layers 10, 20, 30, 40, and 50, the first to third sensing insulation layers TIL1, TIL2, and TIL3, and a conductive pattern MTL-a may be disposed in the bonding area IBA-1 of the display panel DP-3 according to an embodiment.

According to an embodiment, the opening portion IL-OP overlapping with the bonding area IBA-1 may be defined in the sixth and seventh insulation layers 60 and 70. The opening portion IL-OP may expose the fifth insulation layer 50. In more detail, the opening portion IL-OP may be defined between the first and second patterns 60-B and 70-B of the second structure BAD2 and the first and second patterns 60-C and 70-C of the third structure BAD3.

According to the present embodiment, the first sensing insulation layer TIL1, the second sensing insulation layer TIL2, and the conductive pattern MTL-a may expose a side surface 60-S of the sixth insulation layer 60 and a side surface 70-S of the seventh insulation layer 70, each of which is adjacent to the second area A2 and defines the opening portion IL-OP, and a top surface 50-U, which is exposed by the opening portion IL-OP, of the fifth insulation layer 50. The portions exposed by the first sensing insulation layer TIL1, the second sensing insulation layer TIL2, and the conductive pattern MTL-a may be covered by the third sensing insulation layer TIL3.

As described above with reference to FIGS. 9, 10, and 12, the conductive patterns MTL and MTL-a disposed on a cross-section of the data line areas DTL1 and DTL2 described above with reference to FIG. 5B and the bonding area IBA-1 may be in a floating state.

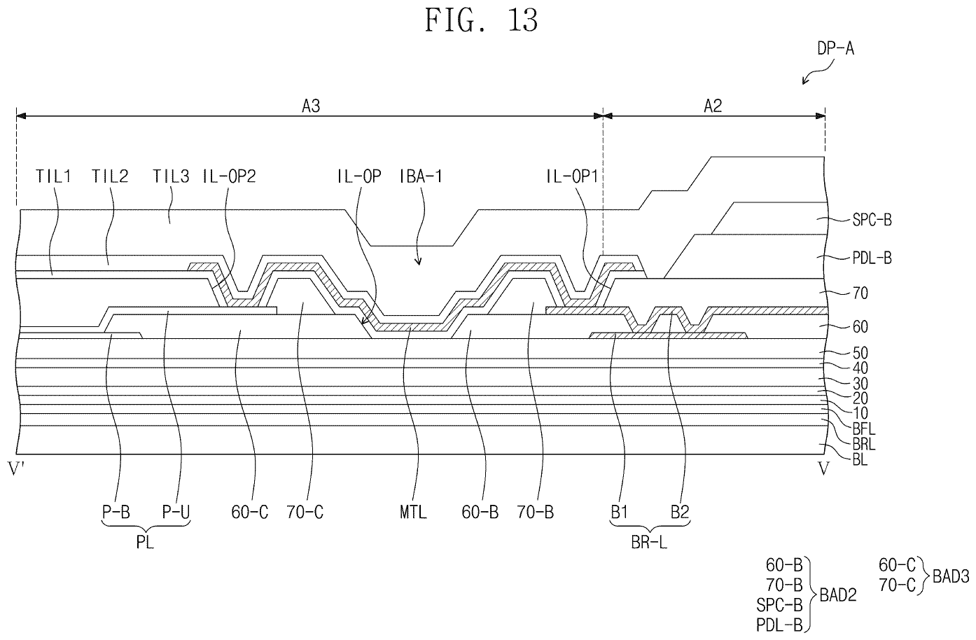

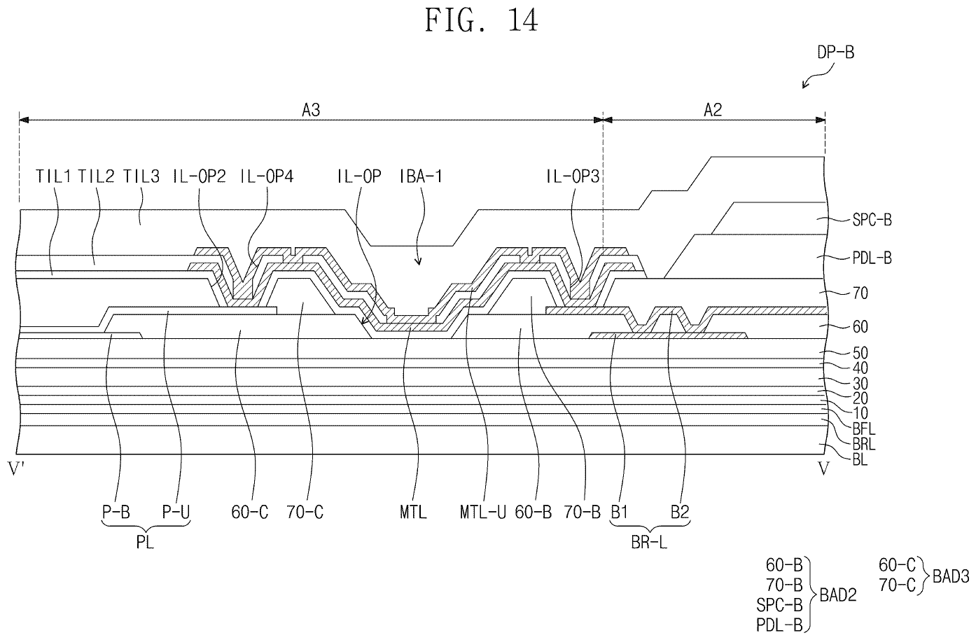

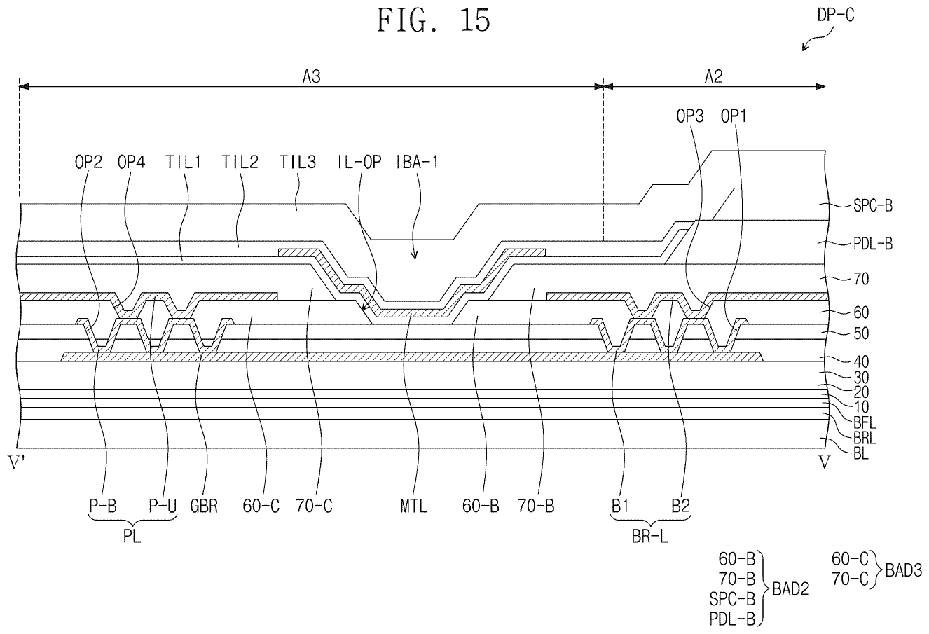

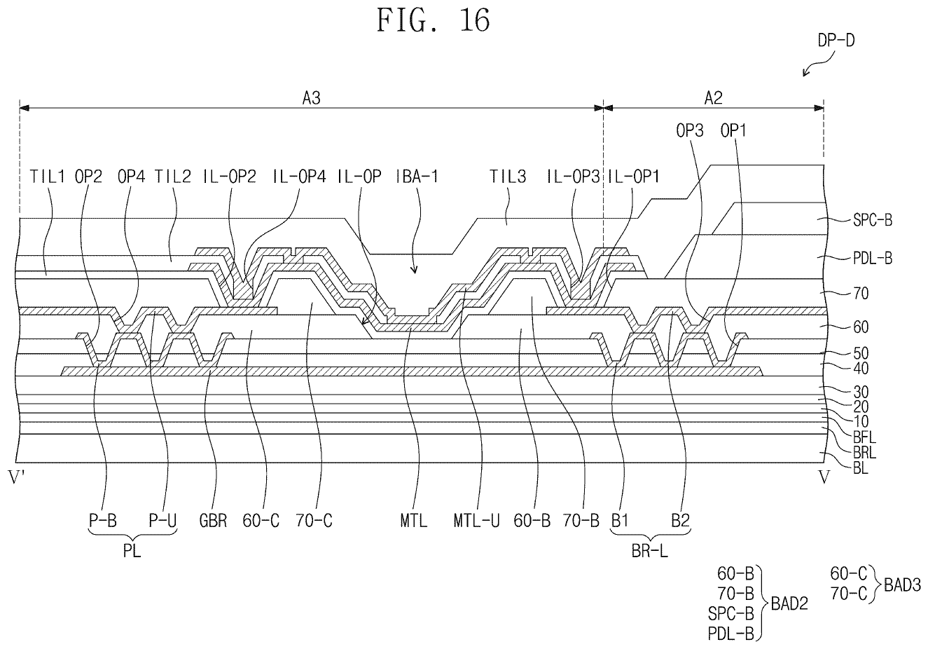

FIG. 13 is a cross-sectional view taken along the line V-V′ in FIG. 5B. FIG. 14 is a cross-sectional view of a bonding area of a display panel according to an embodiment of the present disclosure. FIG. 15 is a cross-sectional view of a bonding area of a display panel according to an embodiment of the present disclosure. FIG. 16 is a cross-sectional view of a bonding area of a display panel according to an embodiment of the present disclosure. For example, FIGS. 13 to 16 are cross-sectional views taken along the line V-V′ in FIG. 5B. In more detail, FIGS. 13 to 16 are cross-sectional views of the bonding area IBA-1 adjacent to the second area A2 and the power line areas VDL, VSL1, and VSL2. The same/similar components as/to those described above with reference to FIG. 8 are designated by the same/similar reference numbers or symbols, and thus, redundant description thereof may not be repeated.

Referring to FIG. 13, a display panel DP-A according to an embodiment may include the bridge pattern BR-L disposed in the second area A2. The bridge pattern BR-L may include a lower layer B1 and an upper layer B2. The lower layer B1 may be disposed on the fifth insulation layer 50, and may be covered by the sixth insulation layer 60. The upper layer B2 may be disposed on the sixth insulation layer 60, and may be covered by the seventh insulation layer 70. The upper layer B2 may be connected to the lower layer B1 through contact holes passing through the sixth insulation layer 60. The upper layer B2 may be connected to the power line PL (e.g., see FIG. 5A) disposed on the sixth insulation layer 60 of the first area A1.

The power line PL disposed in the third area A3 may include a lower layer P-B and an upper layer P-U. The lower layer P-B may be disposed on the fifth insulation layer 50, and may be covered by the sixth insulation layer 60. The upper layer P-U may be disposed on the sixth insulation layer 60, and may be covered by the seventh insulation layer 70. The upper layer P-U may be connected to the lower layer P-B through contact holes passing through the sixth insulation layer 60.

The bonding area IBA-1 adjacent to a boundary of the second area A2 may be defined in the third area A3. The barrier layer BRL, the buffer layer BFL, the first to fifth insulation layers 10, 20, 30, 40, and 50, the first to third sensing insulation layers TIL1, TIL2, and TIL3, and the conductive pattern MTL may be disposed in the bonding area IBA-1.

According to an embodiment, an opening portion IL-OP overlapping with the bonding area IBA-1 may be defined in the sixth and seventh insulation layers 60 and 70. The opening portion IL-OP may expose the fifth insulation layer 50. In more detail, the opening portion IL-OP may be defined between first and second patterns 60-B and 70-B of the second structure BAD2 and first and second patterns 60-C and 70-C of the third structure BAD3.

The conductive pattern MTL may be disposed on the first sensing insulation layer TIL1 within the opening portion IL-OP, and may be covered by the second sensing insulation layer TIL2. The third sensing insulation layer TIL3 may cover the second sensing insulation layer TIL2.

In the present embodiment, the conductive pattern MTL may serve as a bridge that connects the power line PL (e.g., see FIG. 5A) disposed in the first area A1 to a power line PL disposed in the third area A3.

One end of the conductive pattern MTL, which is adjacent to the second area A2, may be connected to the upper layer B2 of the bridge pattern BR-L through a first contact hole IL-OP1 passing through the first sensing insulation layer TIL1 and the seventh insulation layer 70. The other end of the conductive pattern MTL may be connected to the upper layer P-U of the power line PL disposed in the third area A3 through a second contact hole IL-OP2 passing through the first sensing insulation layer TIL1 and the seventh insulation layer 70.

Thus, the power line PL (e.g., see FIG. 5A) disposed in the first area A1 and the power line PL disposed in the third area A3 may be connected to each other through the conductive pattern MTL and the bridge pattern BR-L disposed in the second area A2.

Hereinafter, a display panel DP-B in FIG. 14 will be described in more detail by focusing on the differences from the display panel DP-A described above with reference to FIG. 13. Referring to FIG. 14, the display panel DP-B according to an embodiment may further include an upper conductive pattern MTL-U. The upper conductive pattern MTL-U may be disposed on the second sensing insulation layer TIL2 within the bonding area IBA-1, and may be covered by the third sensing insulation layer TIL3. The upper conductive pattern MTL-U may overlap with the conductive pattern MTL. The upper conductive pattern MTL-U may be disposed in an opening portion IL-OP within the bonding area IBA-1.

According to the present embodiment, the barrier layer BRL, the buffer layer BFL, the first to fifth insulation layers 10, 20, 30, 40, and 50, the first to third sensing insulation layers TIL1, TIL2, and TIL3, the conductive pattern MTL, and the upper conductive pattern MTL-U may be disposed in the bonding area IBA-1.

One end of the conductive pattern MTL may be connected to an upper layer B2 of a bridge pattern BR-L through a first contact hole IL-OP1 passing through the first sensing insulation layer TIL1 and the seventh insulation layer 70. The other end of the conductive pattern MTL may be connected to an upper layer P-U of a power line PL through a second contact hole IL-OP2 passing through the first sensing insulation layer TIL1 and the seventh insulation layer 70.

The upper conductive pattern MTL-U may be connected to the conductive pattern MTL through contact holes IL-OP3 and IL-OP4 passing through the second sensing insulation layer TIL2. One end of the upper conductive pattern MTL-U may be connected to the conductive pattern MTL connected to the upper layer B2 of the bridge pattern BR-L through a third contact hole IL-OP3. The other end of the upper conductive pattern MTL-U may be connected to the conductive pattern MTL connected to the upper layer P-U of the power line PL. According to the present embodiment, as the conductive pattern MTL and the upper conductive pattern MTL-U are provided in a multilayered structure, a resistance may be reduced, and a path through which moisture may be introduced in a direction from the second area A2 to the third area A3 may be blocked (e.g., may be easily blocked).

Referring to FIG. 15, a display panel DP-C according to an embodiment may further include a lower connection pattern GBR. The lower connection pattern GBR may be disposed on the fourth insulation layer 40, and may be covered by the fifth insulation layer 50. In the present embodiment, instead of the conductive pattern MTL, the lower connection pattern GBR may function to connect a bridge pattern BR-L to the power line PL.

A lower layer B1 of the bridge pattern BR-L may be connected to one end of the lower connection pattern GBR through first contact holes OP1 passing through fourth and fifth insulation layers 40 and 50. A lower layer P-B of the power line PL may be connected to the other end of the lower connection pattern GBR through second contact holes OP2 passing through the fourth and fifth insulation layers 40 and 50.

An upper layer B2 of the bridge pattern BR-L may be connected to the lower layer B1 through third contact holes OP3 passing through the sixth insulation layer 60. An upper layer P-U of the power line PL may be connected to the lower layer P-B through fourth contact holes OP4 passing through the sixth insulation layer 60. In the present embodiment, the conductive pattern MTL may be in a floating state.

Hereinafter, a display panel DP-D illustrated in FIG. 16 will be described in more detail by focusing on the differences from the display panel DP-C described above with reference to FIG. 15. Referring to FIG. 16, the display panel DP-D according to an embodiment may further include an upper conductive pattern MTL-U. The upper conductive pattern MTL-U may be disposed on the second sensing insulation layer TIL2 within the bonding area IBA-1, and may be covered by the third sensing insulation layer TIL3. The upper conductive pattern MTL-U may overlap with the conductive pattern MTL. The upper conductive pattern MTL-U may be disposed in the opening portion IL-OP within the bonding area IBA-1.

One end of the conductive pattern MTL may be connected to an upper layer B2 of the bridge pattern BR-L through first contact holes IL-OP1 passing through the first sensing insulation layer TIL1 and the seventh insulation layer 70. The other end of the conductive pattern MTL may be connected to an upper layer P-U of the power line PL through second contact holes IL-OP2 passing through the first sensing insulation layer TIL1 and the seventh insulation layer 70.

The upper conductive pattern MTL-U may be connected to the conductive pattern MTL through contact holes IL-OP3 and IL-OP4 passing through the second sensing insulation layer TIL2. One end of the upper conductive pattern MTL-U may be connected to the conductive pattern MTL connected to the upper layer B2 of the bridge pattern BR-L through a third contact hole IL-OP3. The other end of the upper conductive pattern MTL-U may be connected to the conductive pattern MTL connected to the upper layer P-U of the power line PL.

The display panel DP-D according to an embodiment may further include a lower connection pattern GBR. The lower connection pattern GBR may be disposed on the fourth insulation layer 40, and may be covered by the fifth insulation layer 50.

A lower layer B1 of the bridge pattern BR-L may be connected to one end of the lower connection pattern GBR through first contact holes OP1 passing through the fourth and fifth insulation layers 40 and 50. A lower layer P-B of the power line PL may be connected to the other end of the lower connection pattern GBR through second contact holes OP2 passing through the fourth and fifth insulation layers 40 and 50.

According to the present embodiment, the power line PL disposed in the first area A1 (e.g., see FIG. 5A) and the power line disposed in the third area A3 may be connected to each other through the conductive pattern MTL, the upper conductive pattern MTL-U, the lower connection pattern GBR, and the bridge pattern BR-L. Thus, even when a short-circuit defect occurs in one of the conductive pattern MTL, the upper conductive pattern MTL-U, the lower connection pattern GBR, and/or the bridge pattern BR-L, the power line PL disposed in the first area A1 (e.g., see FIG. 5A) and the power line disposed in the third area A3 may be connected to each other (e.g., may be easily connected to each other) through the other patterns. Accordingly, the display panel DP-D having improved reliability may be provided.

According to some embodiments of the present disclosure, a structure including the insulation layers, each including the inorganic material, that are stacked in the area adjacent to the bending area of the display panel may be included to prevent or substantially prevent a defect in which moisture may be introduced from the bending area. Thus, the display panel having improved reliability may be provided.

Further, product reliability may be improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising:
a first area comprising an active area comprising pixels;
a second area bent around a bending axis extending in a first direction; and
a third area spaced from the first area with the second area therebetween in a second direction crossing the first direction, the third area comprising a driving chip, conductive patterns, and pads; and
an input sensor comprising:
first to third sensing insulation layers on the display panel;
a first conductive layer on the first sensing insulation layer, and covered by the second sensing insulation layer; and
a second conductive layer on the second sensing insulation layer, and covered by the third sensing insulation layer,
wherein the third area further comprises a bonding area extending to opposite ends of the third area in the first direction, the bonding area being located adjacent to the second area, and
wherein the first sensing insulation layer, the second sensing insulation layer, the conductive patterns that are in contact with the first sensing insulation layer and the second sensing insulation layer, and the third sensing insulation layer are located in the bonding area.

2. The display device of claim 1, wherein each of the first sensing insulation layer and the second sensing insulation layer comprises an inorganic material, and
wherein the third sensing insulation layer comprises an organic material.

3. The display device of claim 1, wherein the conductive patterns comprise the same material as that of one of the first conductive layer or the second conductive layer.

4. The display device of claim 1, wherein the display panel comprises:
a base layer;
a light blocking pattern on the base layer;
a barrier layer on the light blocking pattern;
a buffer layer on the barrier layer;
first to seventh insulation layers on the buffer layer;
transistors of each of the pixels;
a pixel defining layer on the seventh insulation layer;
light emitting elements connected to the transistors; and
an encapsulation layer covering the light emitting elements,
wherein each of the barrier layer, the buffer layer, and the first to fifth insulation layers comprises an inorganic material, and
wherein each of the sixth and seventh insulation layers comprises an organic material.

5. The display device of claim 4, wherein, in a cross-section view in the second direction, the base layer, the barrier layer, the buffer layer, and the first to fifth insulation layers are located in the bonding area, and
wherein an opening portion overlapping with the bonding area and exposing the fifth insulation layer is defined in the sixth insulation layer and the seventh insulation layer.

6. The display device of claim 5, wherein the first sensing insulation layer, the conductive patterns, the second sensing insulation layer, and the third sensing insulation layer located in the bonding area overlap with the opening portion.

7. The display device of claim 6, wherein the display panel comprises:
data lines connected to the pixels and the driving chip; and
power lines connected to the pixels and the pads,
wherein the data lines and the power lines are located in the first area and the third area, and are disconnected in the second area, and
wherein the third area comprises a data line area comprising the data lines, and a power line area comprising the power lines.

8. The display device of claim 7, wherein the data lines are located on the second insulation layer, and covered by the third insulation layer,
wherein the power lines are located on the sixth insulation layer, and covered by the seventh insulation layer, and
wherein the display device further comprises:
a first bridge pattern in the second area, and connected to the data lines located in the first area and the data lines located in the third area; and
a second bridge pattern in the second area, and connected to the power lines located in the first area and the power lines located in the third area.

9. The display device of claim 8, wherein an opening portion that passes through the barrier layer, the buffer layer, and the first to fifth insulation layers to expose the base layer is defined in the second area,
wherein a portion of each of the sixth insulation layer, the seventh insulation layer, and the pixel defining layer covers the opening portion, and
wherein the first bridge pattern and the second bridge pattern are located on the sixth insulation layer, and covered by the seventh insulation layer.

10. The display device of claim 8, wherein, in a cross-sectional view of the bonding area and the data line in the second direction, the first bridge pattern is connected to the data lines through a contact hole passing through the third to sixth insulation layers.

11. The display device of claim 8, wherein, in a cross-sectional view of the bonding area and the power line area in the second direction,
one end of a conductive pattern from among the conductive patterns is connected to the second bridge pattern through a first contact hole defined in the seventh insulation layer and the first sensing insulation layer, and another end of the conductive pattern is connected to the power line through a second contact hole defined in the seventh insulation layer and the first sensing insulation layer.

12. The display device of claim 8, further comprising an upper conductive pattern on the second sensing insulation layer within the bonding area, the upper conductive pattern being covered by the third sensing insulation layer and overlapping with the conductive patterns.

13. The display device of claim 12, wherein, in a cross-sectional view of the bonding area and the power line area in the second direction, the upper conductive pattern is connected to a conductive pattern from among the conductive patterns through contact holes defined in the second sensing insulation layer.

14. The display device of claim 13, further comprising a lower connection pattern on the fourth insulation layer, and covered by the fifth insulation layer,
wherein one end of the lower connection pattern is connected to the second bridge pattern, and another end of the lower connection pattern is connected to the power line via the bonding area.

15. The display device of claim 8, further comprising a lower connection pattern on the fourth insulation layer, and covered by the fifth insulation layer,
wherein, in a cross-sectional view of the bonding area and the power line area in the second direction, a conductive pattern from among the conductive patterns is spaced from the second bridge pattern and the power line, and
wherein one end of the lower connection pattern is connected to the second bridge pattern, and another end of the lower connection pattern is connected to the power line via the bonding area.

16. The display device of claim 7, wherein, in a cross-sectional view of the bonding area and the data line area in the second direction,
the first sensing insulation layer, the conductive patterns, and the second sensing insulation layer expose a side surface of each of the sixth and seventh insulation layers, which is adjacent to the second area and defines the opening portion, and a top surface of the fifth insulation layer, and
wherein the third sensing insulation layer covers the exposed side surfaces of the sixth and seventh insulation layers.

17. The display device of claim 4, wherein the encapsulation layer comprises:
a first inorganic encapsulation layer covering the light emitting elements;
a second inorganic encapsulation layer on the first inorganic encapsulation layer; and
an organic encapsulation layer between the first inorganic encapsulation layer and the second inorganic encapsulation layer,
wherein the display device further comprises a dam pattern in the first area adjacent to the second area, the dam pattern comprising a plurality of layers, and
wherein a boundary of the organic encapsulation layer is defined in the first area by the dam pattern.

18. The display device of claim 17, wherein the first inorganic encapsulation layer and the second inorganic encapsulation layer are in contact with each other between the dam pattern and the second area, and
wherein the first inorganic encapsulation layer and the second inorganic encapsulation layer are not located in the second area and the third area.

19. The display device of claim 1, wherein the first area comprises an additional bonding area extending to opposite ends of the first area in the first direction, the additional bonding area being adjacent to the second area, and
wherein the first sensing insulation layer and the second sensing insulation layer are in contact with each other in the additional bonding area.

20. The display device of claim 7, wherein the input sensor comprises trace lines connected to the second conductive layer and the pads,
wherein the third area comprises a trace line area comprising the trace lines, and
wherein the trace line area overlaps with the power line area.
